(19) United States
(12) Patent Application Publication
(10) Pub. No.: US 2016/0351119 A1
(43) Pub. Date: Dec. 1, 2016

(54) DISPLAY APPARATUS

(71) Applicant: JOLED INC., Tokyo (JP)

(72) Inventor: Shinya ONO, Osaka (JP)

(73) Assignee: JOLED INC., Tokyo (JP)

(21) Appl. No.: 15/116,371

(22) PCT Filed: Dec. 22, 2014
(86) PCT No.: PCT/JP2014/006385

§ 371 Date: Aug. 3, 2016

(30) Foreign Application Priority Data
Feb. 6, 2014 (JP) 2014-021634

(51) Int. Cl. G09G 3/3233; H01L 51/00; H01L 51/56; H01L 27/32

(52) U.S. Cl. CPC G09G 3/3233; H01L 27/3276; H01L 27/3265; H01L 51/0005; H01L 51/56; H01L 27/3246; G09G 2300/0842; G09G 2320/0233; G09G 2330/028; G09G 2300/0426; H01L 2227/323

(57) ABSTRACT

An organic EL display apparatus according to the present disclosure has pixels, and includes: a thin-film transistor array device; a light-emitting layer provided above the thin-film transistor array device; banks partitioning the light-emitting layer into linear sections; and power supply lines which are provided for the thin-film transistor array device and supply a predetermined voltage to the pixels. Each of the pixels has: an organic EL element which includes a part of the light-emitting layer partitioned into the linear sections and emits light corresponding to a supplied current; a drive transistor which supplies a current to the organic EL element; and a storage capacitor which stores a threshold voltage of the drive transistor. Each of the power supply lines is arranged to cross the banks as viewed from above.

### TECHNICAL FIELD

The present invention relates to a display apparatus.

### BACKGROUND ART

As a display apparatus including current-driven light-emitting elements, a display apparatus including organic electroluminescent (EL) elements is known. Such an organic EL display apparatus including organic EL elements, which are self-luminous elements, does not require a backlight that is necessary for a liquid crystal display apparatus, and thereby is most suitable for achieving a thinner display apparatus. In addition, having an unlimited viewing angle, the organic EL display apparatus is hoped to be commercially practical as a next-generation display apparatus.

For example, Patent Literature (PTL) 1 discloses a configuration of an active-matrix display apparatus in which power supply wiring is enhanced to achieve pixels with higher resolution.

### CITATION LIST

### Patent Literature

[PTL 1] Japanese Unexamined Patent Application Publication No. 2008-65199

### SUMMARY OF INVENTION

### Technical Problem

However, such a display apparatus may possibly cause display unevenness.

In view of this, the present disclosure provides a display apparatus that can reduce display unevenness.

### Solution to Problem

A display apparatus according to an aspect of the present disclosure has a plurality of pixels and includes: a circuit substrate; a light-emitting layer which is provided above the circuit substrate; a plurality of first partitions which partition the light-emitting layer into a plurality of linear sections; and a plurality of power supply lines which are provided for the circuit substrate and supply a predetermined voltage to the plurality of pixels, wherein each of the plurality of pixels has: a light-emitting element which includes a part of the light-emitting layer partitioned into the plurality of linear sections and emits light corresponding to a supplied current; a drive transistor which supplies a current to the light-emitting element; and a storage capacitor which stores a threshold voltage of the drive transistor, and each of the plurality of power supply lines is arranged to cross the plurality of first partitions as viewed from above.

### Advantageous Effects of Invention

The display apparatus according to the present disclosure can reduce display unevenness.

### BRIEF DESCRIPTION OF DRAWINGS

FIG. 1 is a partially-cutaway perspective view of an organic EL display apparatus according to Embodiment 1.

FIG. 2 is a perspective view showing an example of banks of the organic EL display apparatus according to Embodiment 1.

FIG. 3 is a cross-sectional view showing a pixel configuration according to Embodiment 1.

FIG. 4 is an electric circuit diagram showing a configuration of a pixel circuit included in the organic EL display apparatus according to Embodiment 1.

FIG. 5 is a timing chart showing an operation of the pixel circuit included in the organic EL display apparatus according to Embodiment 1.

FIG. 6 is an explanatory view showing a state of the pixel circuit in a Vth detection period shown in FIG. 5.

FIG. 7 is an explanatory view showing a state of the pixel circuit in a light emission period shown in FIG. 5.

FIG. 8 is a diagram showing an arrangement of power supply lines (VREF lines) and the banks in the organic EL display apparatus according to Embodiment 1.

FIG. 9 is a diagram showing another example of the arrangement of first RESET lines in the organic EL display apparatus according to Embodiment 1.

FIG. 10 is a diagram showing another example of the arrangement of the first RESET lines in the organic EL display apparatus according to Embodiment 1.

FIG. 11 is an electric circuit diagram showing a configuration of a pixel circuit included in an organic EL display apparatus according to Modification of Embodiment 1.

FIG. 12 is a diagram showing an arrangement of power supply lines (DATA lines) and banks in the organic EL display apparatus according to Modification of Embodiment 1.

FIG. 13 is an explanatory view showing a state of a pixel circuit in a Vth detection period shown in FIG. 5, according to Embodiment 2.

FIG. 14 is a graph showing I-V characteristics of a drive transistor according to Embodiment 2.

FIG. 15 is a diagram showing an arrangement of power supply lines (VDD lines) and banks in an organic EL display apparatus according to Embodiment 2.

FIG. 16 is an explanatory view showing a state of a pixel circuit in an EL reset period shown in FIG. 5, according to Embodiment 3.

FIG. 17 is a diagram showing an arrangement of power supply lines (VRST lines) and banks in an organic EL display apparatus according to Embodiment 3.

FIG. 18 is a perspective view showing an example of banks in an organic EL display apparatus according to another modification.

FIG. 19 is a diagram showing an arrangement of power supply lines (VREF lines, for example) and banks in an organic EL display apparatus according to another modification.

FIG. 20 is a diagram showing an arrangement of power supply lines (VREF lines, for example) and banks in an organic EL display apparatus according to another modification.

FIG. 21 is an external view of a thin flat screen TV including a display apparatus according to the present disclosure.

### DESCRIPTION OF EMBODIMENTS

### Underlying Knowledge Forming Basis of the Present Disclosure

Before the description of Embodiments, the underlying knowledge forming the basis of the present disclosure is described.

In a display apparatus including organic EL elements, a light-emitting layer of the organic EL element may be formed by a wet film-forming method, such as an ink-jet method, in some cases, By the ink-jet method, the light-emitting layer is formed by dropping a solution of an organic semiconductor material to a pixel row (or a pixel column) located between partitions (also referred to as banks) formed in, for example, linear shapes. This means that the display apparatus includes a plurality of light-emitting layers in the forms of linear sections, each of which is partitioned by two adjacent partitions.

Such partitioned linear sections as the light-emitting layers may possibly vary in thickness, depending on the amount and concentration of the organic semiconductor material solution dropped at the time of layer formation and on a drying condition. For example, when the light-emitting layer is partitioned by the partitions by pixel row (or by pixel column), the light-emitting layer formed in one same pixel row (or one same pixel column) may be almost uniform in thickness. In this case, however, the light-emitting layers formed in different pixel rows (or different pixel columns) may possibly have different thicknesses.

In other words, in the display apparatus having a plurality of linear sections as the light-emitting layers formed by the wet film-forming method, such as the ink-jet method, the thickness may possibly be different for each of the linear sections of the light-emitting laye.

The inventors have found that such thickness variations among the linear sections of the light-emitting layer cause display unevenness. In view of this, the inventors were able to conceive the idea of reducing the display unevenness caused by the thickness variations among the linear sections of the light-emitting layer.

To be more specific, a display apparatus according to an aspect of the present disclosure has a plurality of pixels and includes: a circuit substrate; a light-emitting layer which is provided above the circuit substrate; a plurality of first partitions which partition the light-emitting layer into a plurality of linear sections; and a plurality of power supply lines which are provided for the circuit substrate and supply a predetermined voltage to the plurality of pixels, wherein each of the plurality of pixels has: a light-emitting element which includes a part of the light-emitting layer partitioned into the plurality of linear sections and emits light corresponding to a supplied current; a drive transistor which supplies a current to the light-emitting element; and a storage capacitor which stores a threshold voltage of the drive transistor, and each of the plurality of power supply lines is arranged to cross the plurality of first partitions as viewed from above.

In this way, each of the power supply lines is arranged to cross the first partitions as viewed from above and thereby is electrically connected to the light-emitting elements including the linear sections of the light-emitting layer partitioned into the linear sections. Thus, each of the power supply lines can be regarded as being connected to, as load, the capacitive components of the light-emitting elements including the linear sections of the light-emitting layer. On account of this, even when the thickness is different for each of the linear sections of the light-emitting layer, the load on the power supply line is less likely to depend on the thickness of the specific linear section of the light-emitting layer. This results in reduced variations in the amount of voltage drop among the power supply lines. With the variations in the amount of voltage drop among the power supply lines, a streak pattern corresponding to the first partitions may possibly be displayed. According to the display apparatus according to the present disclosure, the power supply lines are less likely to vary in the amount of voltage drop. Hence, the streak pattern displayed can be reduced. In other words, the display unevenness can be reduced.

Moreover, the display apparatus may further include a plurality of second partitions which are arranged to cross the plurality of first partitions and partition, in conjunction with the plurality of first partitions, the light-emitting layer into a grid of squares, wherein the plurality of first partitions may protrude upward higher than the plurality of second partitions.

With this, the light-emitting layer can be formed in the openings of the grid by a simple manufacturing process.

Furthermore, the light-emitting element may further include an anode and a cathode which are provided above the circuit substrate and disposed opposite to each other via the part of the light-emitting layer partitioned into the plurality of linear sections, and the light-emitting layer may include a hole injection layer, a hole transport layer, an organic light-emitting layer, an electron transport layer, and an electron injection layer which are laminated from an anode side in stated order.

Moreover, at least one of the hole injection layer, the hole transport layer, the organic light-emitting layer, the electron transport layer, and the electron injection layer may be formed by a printing method.

Here, the layer formed by the printing method may possibly have thickness variations among the linear sections of the light-emitting layer. To be more specific, when at least one of the hole injection layer, the hole transport layer, the organic light-emitting layer, the electron transport layer, and the electron injection layer included in the light-emitting layer is formed by the printing method, the light-emitting layer may possibly vary in thickness among the linear sections. However, the arrangement in which each of the power supply lines crosses the first partitions can reduce the display unevenness even when at least one of these layers included in the light-emitting layer is formed by the printing method.

Furthermore, each of the plurality of power supply lines may be arranged to be orthogonal to the plurality of first partitions as viewed from above.

Moreover, the storage capacitor may have: a first electrode which is electrically connected to a gate of the drive transistor; and a second electrode which is electrically connected to a source of the drive transistor and to an anode of the light-emitting element. The display apparatus may include: a plurality of reference voltage supply lines which supply a reference voltage used as a reference to detect the threshold voltage for each of the plurality of pixels; and a plurality of positive supply lines each of which is electrically connected to a drain of the drive transistor and supplies a current that causes the light-emitting element of the pixel to emit light. Each of the plurality of pixels may further have a first switch for switching a state between the reference voltage supply line and the first electrode of the storage capacitor, between conducting and non-conducting states. At least one of the plurality of reference voltage supply lines and the plurality of positive supply lines may be the plurality of power supply lines.

Here, when the threshold voltage of the drive transistor is detected, at least a part of a threshold detection current for detecting the threshold voltage passes through the reference voltage supply line and the positive supply line. This causes voltage drops. The voltage drop caused to the reference voltage supply line influences a current that passes through the pixel during light emission. The voltage drop caused to the positive supply line influences the result of the detection of the threshold voltage of the drive transistor. Thus, the display unevenness is caused in either of the following two cases, that is, the case of the variations in the amount of voltage drop among the reference voltage supply lines and the case of the variations in the amount of voltage drop among the positive supply lines. However, the arrangement in which at least one of the plurality of reference voltage supply lines and the plurality of positive supply lines cross the first partitions can reduce the variations in the amount of voltage drop among the lines that cross the first partitions. Hence, the display unevenness can be reduced.

Furthermore, the display apparatus may include a plurality of signal lines, as the plurality of reference voltage supply lines, which supply the reference voltage and a signal voltage that determines luminance of the plurality of pixels.

In this way, the signal lines substitute for the reference voltage supply lines for supplying the reference voltage, and thereby the number of wiring lines can be reduced. Thus, the layout design can be easily created.

Moreover, the storage capacitor may have: a first electrode which is electrically connected to a gate of the drive transistor; and a second electrode which is electrically connected to a source of the drive transistor and to an anode of the light-emitting element. The display apparatus may include: a plurality of reset power supply lines which supply a reset voltage for resetting a voltage held by the light-emitting element for each of the plurality of pixels; and a plurality of positive supply lines each of which is electrically connected to a drain of the drive transistor and supplies a current that causes the light-emitting element of the pixel to emit light. Each of the plurality of pixels may further have a second switch for switching a state between the reset power supply line and the second electrode of the storage capacitor and a state between the reset power supply line and the anode of the light-emitting element, between conducting and non-conducting states. At least one of the plurality of reset power supply lines and the plurality of positive supply lines may be the plurality of power supply lines.

Here, when the electrical charge accumulated in the capacitance component of the organic EL element is reset to detect the threshold voltage of the drive transistor, the current corresponding to this electrical charge passes through the reset power supply line and thereby causes the voltage drop. The voltage drop caused to the reset power supply line influences the result of the detection of the threshold voltage of the drive transistor. Thus, the variations in the amount of voltage drop among the reset power supply lines cause the display unevenness. Moreover, as described above, the variations in the amount of voltage drop among the positive supply lines also cause the display unevenness. However, the arrangement in which at least one of the plurality of reset power supply lines and the plurality of positive supply lines cross the first partitions can reduce the variations in the amount of voltage drop among the lines that cross the first partitions. Hence, the display unevenness can be reduced.

Hereinafter, an aspect of the display apparatus according to the present disclosure is described specifically with reference to the accompanying drawings. It should be noted that excessively detailed description may be omitted. For example, detailed descriptions on well-known matters and redundant descriptions on the substantially same structural elements may be omitted. Such an omission is made to avoid unnecessary prolixity in the following description and to facilitate understanding by those skilled in the art.

Although the inventors provide the accompanying drawings and the following description to make the present disclosure fully understandable for those skilled in the art, these accompanying drawing and the following description are not intended to limit the subject matters described in the claims. For example, the numerical values, shapes, materials, structural elements, the arrangement and connection of the structural elements, and so forth described in the following exemplary embodiments below are mere examples, and are not intended to limit the present disclosure. Furthermore, among the structural elements in the following exemplary embodiments below, structural elements not recited in any one of the independent claims indicating top concepts according to the present disclosure are described as arbitrary structural elements. Note also that each of the drawings are only schematic diagrams and are not necessarily precise representations.

### Embodiment 1

An organic EL display apparatus according to Embodiment 1 is a display apparatus according to an aspect of the present disclosure. The organic EL display apparatus includes a plurality of power supply lines each of which is arranged, as viewed from above, to cross a plurality of banks that partition a light-emitting layer into linear sections. The following is a specific description on the organic EL display apparatus according to Embodiment 1.

### [Organic EL Display Apparatus]

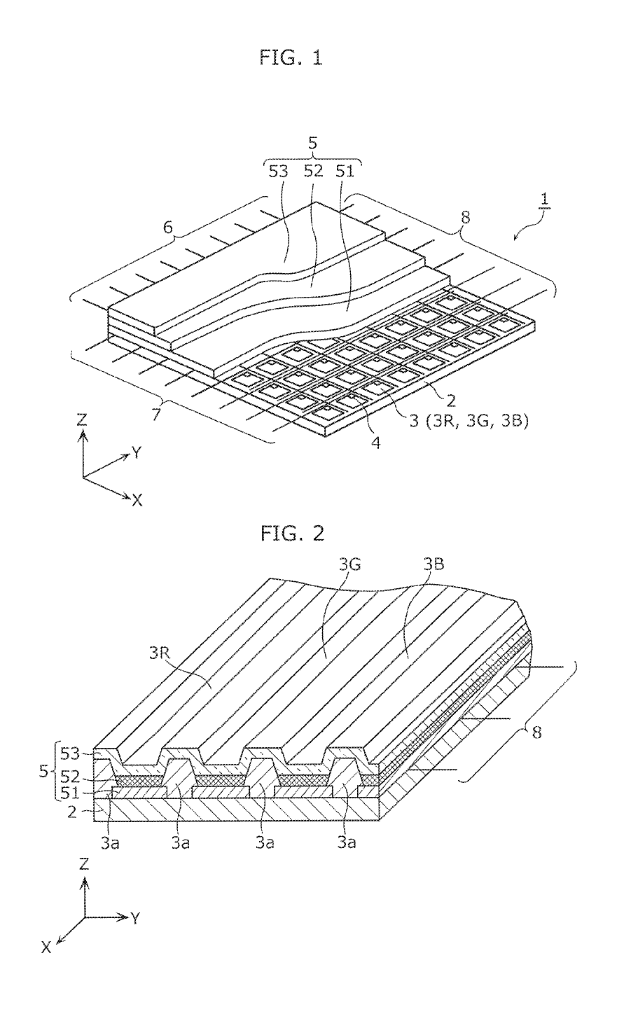

First, a configuration of an organic EL display apparatus 1 according to Embodiment 1 is described, with reference to FIG. 1 to FIG. 3. FIG. 1 is a partially-cutaway perspective view of the organic EL display apparatus according to Embodiment 1. FIG. 2 is a perspective view showing an example of banks of the organic EL display apparatus according to Embodiment 1. In FIG. 1, both an anode 51 and a light-emitting layer 52 are illustrated to cover a whole surface. However, to be more specific, the anode 51 is divided for each of pixels 3 and the light-emitting layer 52 is partitioned into the linear sections. In the following description, a Z-axis direction may refer to the vertical direction and the positive side of the Z-axis direction may refer to the upper side, for convenience of explanation. However, note that the Z-axis direction is not always the vertical direction in an actual usage.

As shown in FIG. 1, the organic EL display apparatus 1 is formed by stacking the following from the bottom: a thin-film transistor array device (circuit substrate) 2 on which a plurality of thin-film transistors are arranged; and an organic EL element 5 (a light-emitting element) including the anode 51 which is a lower electrode, the light-emitting layer 52 which has an organic light-emitting layer comprising an organic material, and a cathode J-which is an upper transparent electrode. To be more specific, the organic EL display apparatus 1 includes the following: the thin-film transistor array device 2; the light-emitting layer 52 which is provided above the thin-film transistor array device 2; a plurality of banks 3a (first partitions) which partition the light-emitting layer 52 into a plurality of linear sections; and a plurality of power supply lines 8 which are provided for the thin-film transistor array device 2 and supply a predetermined voltage to the pixels 3.

The thin-film transistor array device 2 includes the pixels 3 arranged in a matrix. Each of the pixels 3 includes a part of the light-emitting layer 52 partitioned into the linear sections and is provided with a pixel circuit 4. Each of the pixels 3 corresponds to one of the color pixels (which are a red pixel 3R, a green pixel 3G, and a blue pixel 3B). Note that the configurations of these pixels 3R, 3G, and 3B are identical except that the colors displayed by these pixels are different. Thus, the pixels 3R, 3G, and 3B may not be particularly distinguished from each other and may be simply described as the pixel 3 hereinafter.

The organic EL element 5 is formed for each of the pixels 3. The light emission of the organic EL element 5 is controlled by the pixel circuit 4 of the corresponding pixel 3. The organic EL element 5 is formed on an interlayer insulating film (a flattening film) that is formed in a manner to cover the thin-film transistors.

Moreover, the organic EL element 5 has a configuration in which the light-emitting layer 52 is interposed between the anode 51 and the cathode 53, which are a pair of electrodes. The light-emitting layer 52 includes the organic light-emitting layer comprising the organic material. A specific configuration of the light-emitting layer 52 is described later.

Drive of each of the pixels 3 is controlled by the corresponding pixel circuit 4. The thin-film transistor array device 2 is provided with the following: a plurality of SCAN lines (scanning lines) 6 arranged along the direction of rows of the pixels 3 (the direction parallel to the X axis); a plurality of DATA lines (signal lines) 7 arranged along the direction of columns of the pixels 3 (the direction parallel to the Y axis) to cross the SCAN lines 6; and the plurality of power supply lines 8 (in Embodiment 1, VREF lines described later). The pixels 3 are partitioned by, for example, the SCAN lines 6 and the DATA lines 7 that are orthogonal to each other. A specific configuration of the pixel circuit 4 is described later.

The power supply lines 8 supply the predetermined voltage to the pixels 3. Each of the power supply lines 8 is arranged to cross the banks 3a, as viewed from above (i.e., as viewed from the positive side of the Z-axis direction). For example, each of the power supply lines 8 is arranged to be orthogonal to the banks 3a, as viewed from above.

Examples of the lines that supply the predetermined voltage to the pixels 3 include VREF lines, VDD lines, VSS lines, and VRST lines described later. In Embodiment 1, the VREF lines are used as the power supply lines 8, for example. Thus, in Embodiment 1, the VDD lines, the VSS lines, and the VRST lines, which are the power supply lines other than the VREF lines, may be arranged in parallel to the banks 3a, as viewed from above (i.e., as viewed from the positive side of the Z-axis direction).

### [Pixel]

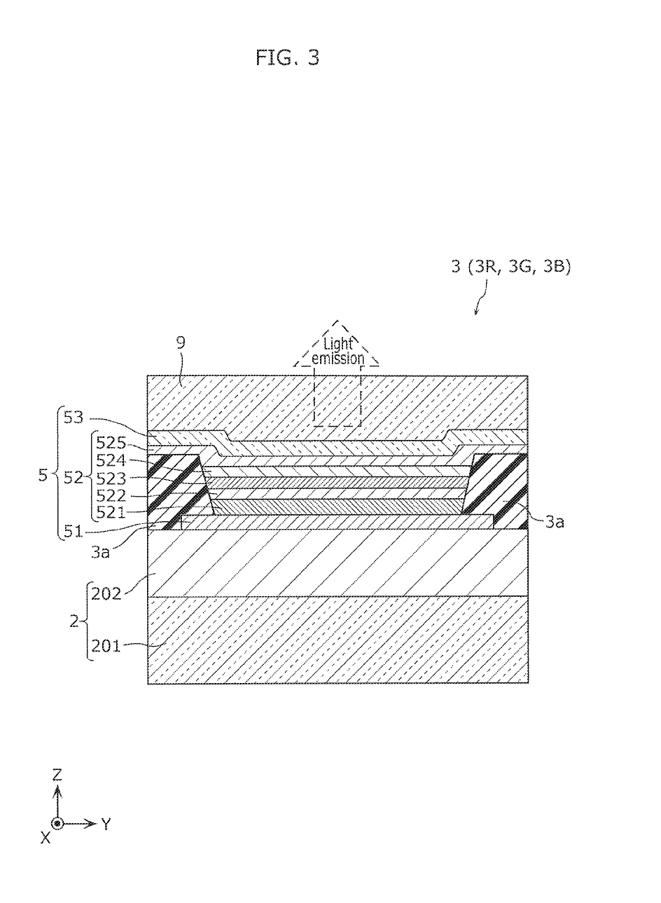

Here, a specific configuration of the pixel 3 is described with reference to FIG. 3. FIG. 3 is a cross-sectional view showing a configuration of the pixel 3 according to Embodiment 1.

As shown in FIG. 3 and FIG. 1, the pixel 3 is formed by stacking the following from the bottom: the thin-film transistor array device (circuit substrate) 2 on which the thin-film transistors are arranged; and the organic EL element 5 including the anode 51 which is the lower electrode, the light-emitting layer 52 which has the organic light-emitting layer comprising the organic material, and the cathode which is the upper transparent electrode. Although the illustration is omitted in FIG. 1, the pixel 3 is provided with a transparent sealing film 9 laminated on the cathode 53 of the organic EL element 5.

The thin-film transistor array device 2 includes, from the bottom, a substrate 201 and a drive circuit layer 202 formed on the substrate 201.

The substrate 201 is a structural component in the form of a plate on which the pixels 3 are arranged in a matrix with rows and columns. For example, the substrate 201 is a glass substrate. Moreover, a flexible substrate comprising a resin, for example, can be used as the substrate 201. In the case of the top emission structure as shown in FIG. 3, the substrate 201 does not need to be transparent and thus a non-transparent substrate, such as a silicon substrate or a metal plate, may also be used.

The drive circuit layer 202 includes the pixel circuit 4 which controls the light emission of the organic EL element 5. To be more specific, the pixel circuit 4 formed in the drive circuit layer 202 includes a thin-film transistor which is a drive transistor for supplying a current to the organic EL element 5. The flattening film maintains the flatness of the upper surface of this drive circuit layer 202.

As shown in FIG. 3, FIG. 1, and FIG. 2, the organic EL element 5 is formed by stacking the following: the anode 51 which is the lower electrode; the light-emitting layer 52 which has the organic light-emitting layer comprising at least the organic material; and the thode 53 which is the upper transparent electrode.

The anode 51 is provided for each of the pixels 3, and is laminated on the surface of the flattening film of the drive circuit layer 202 to apply a positive voltage to the light-emitting layer 52 with respect to the cathode 53. The anode 51 and the corresponding pixel circuit 4 are electrically connected to each other via a contact hole and a relay electrode. As an anode material of the anode 51, it is preferable to use, for example, Al or Ag each of which is a metal with a high reflectivity, or an alloy of these metals. The anode 51 has a thickness of 100 nm to 300 nm, for example.

The light-emitting layer 52 includes a hole injection layer 521, a hole transport layer 522, an organic light-emitting layer 523, an electron transport layer 524, and an electron injection layer 525. This light-emitting layer 52 is partitioned by the banks 3a formed in linear shapes, into the linear sections (into the shapes of strips) as viewed from above (i.e., as viewed from the positive side of the Z-axis direction).

Here, the expression “the light-emitting layer 52 is partitioned” does not necessarily mean that the plurality of layers (the hole injection layer 521, the hole transport layer 522, the organic light-emitting layer 523, the electron transport layer 524, and the electron injection layer 525) included in the light-emitting layer 52 are all divided as viewed from above. This expression means that at least the organic light-emitting layer 523 among the layers included in the light-emitting layer 52 is divided as viewed from above. More specifically, at least one of the hole injection layer 521, the hole transport layer 522, the electron transport layer 524, and the electron injection layer 525 does riot need to be divided. Thus, the expression “the light-emitting layer 52 is partitioned” means, for example, that it is only required that the organic-light-emitting layer 523 that determines the color of this light-emitting layer 52 is divided.

The light-emitting layer 52 formed in the linear section as a result of being partitioned along the direction of rows of the pixels 3 is arranged to correspond to the pixels 3 in the same row. Thus, each of the organic EL elements 5 of the pixels 3 includes a part of the light-emitting layer 52 partitioned into the linear sections.

For example, the pixels 3 of the same color are arrange in the same row. Thus, each of the linear sections of the light-emitting layer 52 is arranged to correspond to one of the colors of the pixels 3. To be more specific, one of the linearly-partitioned light-emitting layers 52 corresponds to the red pixel 3 (the pixel 3R), and another one of the linearly-partitioned light-emitting layers 52 corresponds to the green pixel 3 (the pixel 3G). That is, for example, the light-emitting layer 52 among the linearly-partitioned light-emitting layers 52 is arranged to cover the anodes 51 of the pixels 3 in the same row (with the same color).

In other words, the banks 3a partition the light-emitting layer 52 into a plurality of linear sections. For example, the banks 3a are formed between the adjacent pixels 3 of different colors in a manner that the pixels 3 are divided by color.

To be more specific, each of the banks 3a is formed on the surface of the anode 51, and has a function as a partition to form, in a predetermined region, the hole injection layer 521, the hole transport layer 522, the organic light-emitting layer 523, or the electron transport layer 524 that is formed by, for example, the wet film-forming method, such as the ink-jet method. A material used for the bank 3a may be either inorganic or organic. However, since high liquid repellency and a great film thickness (height) are required at the same time, it is common that an organic material is more preferably used. Examples of such a material include resins, such as a polyimide resin and a polyacrylic resin that contain fluorine. The bank 3a has a thickness of 100 nm to 3000 nm, for example.

The hole injection layer 521 is formed on the surface of the anode 51, and has a function of injecting holes to the organic light-emitting layer 523 with stability or in a manner that hole generation is assisted. With this, a drive voltage of the light-emitting layer 52 is reduced. In addition, the stable hole injection extends a life span of the element. As a material for the hole injection layer 521, poiyethylenedioxythiophene (PEDOT) can be used, for example. Moreover, the thickness of the hole injection layer 521 is preferably about 10 nm to 100 nm, for example.

The hole transport layer 522 is formed on the surface of the hole injection layer 521, and has the following function: transporting the holes injected from the hole injection layer 521 into the organic light-emitting layer 523 with efficiency; preventing deactivation of excitons caused at an interface between the organic light-emitting layer 523 and the hole injection layer 521; and blocking electrons. Examples of the material for the hole transport layer 522 include not only a low-molecular organic material, but also a light-emitting polymeric organic material with which the layer can be formed by the wet film-forming method, such as the ink-jet method. Moreover, the hole transport layer 522 has a thickness of 5 nm to 50 nm, for example.

It should be noted that the hole transport layer 522 may be omitted in some cases, depending on the materials used for the adjacent layers, which are the hole injection layer 521 and the organic light-emitting layer 523.

The organic light-emitting layer 523 is formed on the surface of the hole transport layer 522, and has a function of causing the injected holes and electrons to recombine with each other to generate an excited state for light emission. Examples of the material for the organic light-emitting layer 523 include not only a low-molecular organic material, but also a light-emitting polymeric organic material with which the layer can be formed by the wet film-forming method, such as the ink-jet method. The polymeric organic material is characterized by, for example, achieving a simple device configuration, a film of high reliability, and a low-voltage driven device. As the polymeric organic material for the organic light-emitting layer 523, polymers with a conjugated system, such as an aromatic ring or a condensed ring, or polymers with a n-conjugated system can be used because of the fluorescent properties. Examples of the polymeric light-emitting material used for the organic light-emitting layer 523 include polyphenylene vinylene (PPV) or a derivative thereof (a PPV derivative), polyfluorene (PFO) or a derivative thereof (a PFO derivative), and a polyspirofluorene derivative. Alternatively, polythiophene or a derivative thereof can also be used. The thickness of the organic light-emitting layer 523 is about 10 nm to 100 nm, for example.

The electron transport layer 524 is formed on the surface of the organic light-emitting layer 523, and has the following function: transporting the electrons injected from the electron injection layer 525 into the organic light-emitting layer 523 with efficiency; preventing deactivation of excitons caused at an interface between the organic light-emitting layer 523 and the electron injection layer 525; and blocking the electrons. Examples of the material for the electron transport layer 524 include a nitro-substituted fluorenone derivative, a thiopyran dioxide derivative, a diphenoguinone derivative, a perylenetetracarboxylic derivative, an anthraquinodimethane derivative, a fluorenylidenemethane derivative, an anthrone derivative, an oxadiazole derivative, a perinone derivative, and a quinoline complex derivative. The thickness of the electron transport layer 524 is about 0.5 nm to 50 nm, for example.

The electron injection layer 525 is formed on the organic light-emitting layer 523, and has the following function: reducing barriers to injecting electrons into the organic light-emitting layer 523 to reduce the drive voltage of the light-emitting layer 52; and reducing deactivation of excitons. With this, the stable electron injection extends a life span of the element. In addition, the injection of the electrons balanced in amount with the holes injected from the hole injection layer 521 can enhance the generation efficiency of photons in the light-emitting layer. Examples of the material for the electron injection layer 525 preferably include, but not particularly limited to, barium, aluminum, phthalocyanine, lithium fluoride, and a barium-aluminum laminate. The thickness of the electron injection layer 525 is about 2 nm to 50 nm, for example.

The cathode 53 is laminated on the surface of the electron injection layer 525, and has a function of applying a negative voltage to the light-emitting layer 52 with respect to the anode 51 and injecting the electrons into the element (the organic light-emitting layer 523 in particular). The material for the cathode 53 is not limited to a particular material. However, it is preferable to use a material or a structure having high transmittance. Such a material can achieve a top-emission organic EL element having high luminous efficiency. Examples of the cathode 53 includes, but not particularly limited to, a metal-oxide layer and a thin-film metal layer. Examples of the metal-oxide layer includes, but not particularly limited to, an indium tin oxide (hereinafter, described as ITO) layer and an indium zinc oxide (hereinafter, described as IZO) layer. The thin-film metal layer is a single-layer film comprising one of, a multilayer film comprising, or a co-evaporated film comprising, for example, Al, Ag, and Mg. The thickness of the cathode 53 is about 5 nm to 200 nm, for example.

The transparent sealing film 9 is formed on the surface of the cathode 53, and has a function of protecting the elements from moisture. The transparent sealing film 310 is required to be transparent. The transparent sealing film 9 comprises, for example, SIN, SION, or an organic film. The thickness of the transparent sealing film 9 is about 20 nm to 5000 nm, for example.

With the configuration of the pixel 3 as described thus far, the organic EL display apparatus 1 has a function as a top-emission active-matrix display apparatus. The pixels 3R, 3G, and 3B are divided by color by the banks 3a. These banks 3a are formed in the shapes of for example, linear ridges. Parts between the adjacent ridges correspond to the colors of the pixels 3R, 3G, and 3B on a one-to-one basis.

### [Pixel Circuit]

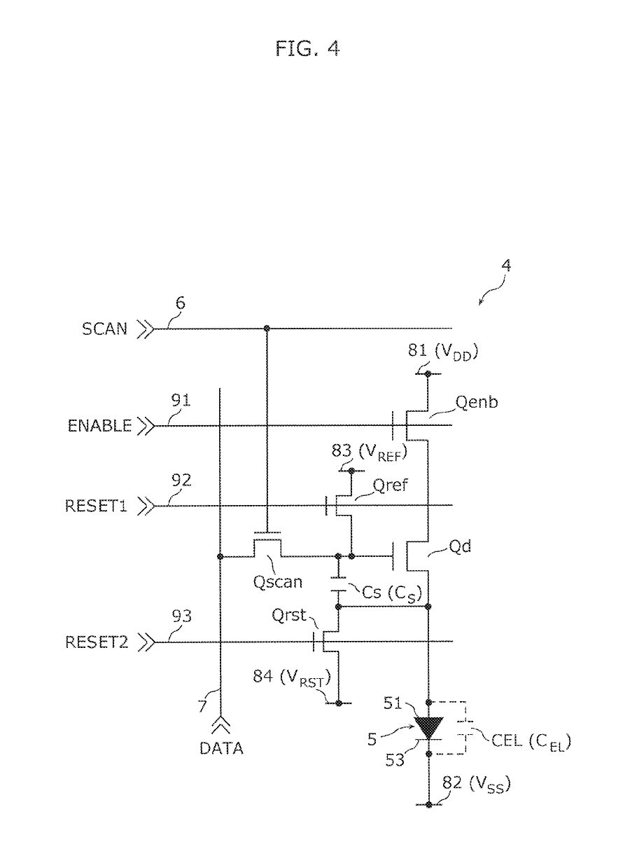

Next, the pixel circuit 4 provided for the pixel 3 is described in detail with reference to FIG. 4 to FIG. 6.

### {Circuit Configuration}

First, the configuration of the pixel circuit 4 is described with reference to FIG. 4. FIG. 4 is an electric circuit diagram showing the configuration of the pixel circuit 4 included in the organic EL display apparatus 1 according to Embodiment 1.

As described above, the pixel circuit 4 controls the light emission of the organic EL element 5. The pixel circuit 4 includes a drive transistor Qd, a transistor Qscan, a transistor Qref (a first switch), a transistor Qrst (a second switch), a transistor Qenb, the organic EL element 5, and a storage capacitor Cs. Moreover, the pixel circuit 4 is connected to the SCAN line 6, the DATA line 7, a VREF line 83 (a reference voltage supply line), a VDD line 81 (a positive supply line), a VSS line 82 (a negative supply line), a VRST line 84 (a reset power supply line), an ENABLE line 91, a first RESET line 92, and a second RESET line 93.

The VREF line 83 is a power supply line for supplying a reference voltage V_{REF}, which is a reference voltage to detect a threshold voltage of the drive transistor Qd. The VDD line 81 for supplying a voltage V_{DD} is a power supply line for supplying a current to cause the organic EL element 5 to emit light. The VSS line 82 for supplying a voltage V_{SS} is a power supply line which is connected to the cathode 53 of the organic: EL element 5. The VRST line 84 for supplying a voltage V_{RST} is a power supply line for resetting the voltages of the organic EL element 5 and the storage capacitor Cs.

The organic EL element 5 emits light having the amount of luminescence corresponding to the amount of current supplied from the drive transistor Qd. In the organic EL element 5, the cathode 53 is connected to the VSS line 82 and the anode 51 is connected to a source of the drive transistor Qd. Here, the voltage V_{SS} supplied to the VSS line 82 is, for example, 0 V.

The drive transistor Qd is a drive element for voltage driving to control the amount of current to be supplied to the organic EL element 5, and causes the organic EL element 5 to emit light by passing the current (pixel current) through the organic EL element 5. To be more specific, the drive transistor Qd has a gate that is connected to a first electrode of the storage capacitor Cs, and a source that is connected to a second electrode of the storage capacitor Cs and to the anode 51 of the organic EL element 5.

The drive transistor Qd causes the organic EL element 5 to emit light by passing the pixel current corresponding to a DATA signal voltage V_{DATA} (a signal voltage), when the transistor Qref is in an off-state (a non-conducting state) and thus the VREF line 83 and the first electrode of the storage capacitor Cs are not conducting and also the transistor Qenb is in an on-state (a conducting state) and thus the VDD line 81 and the drain are conducting. Here, the voltage V_{DD} supplied to the VDD line 81 is, for example, 20 V. With this, the drive transistor Qd converts the DATA signal voltage V_{DATA} supplied to the gate into the pixel current corresponding to this DATA signal voltage V_{DATA} and then supplies the converted pixel current to the organic EL element 5.

Moreover, the threshold voltage of the drive transistor Qd may vary, in some cases, for each of the pixel circuits 4 depending on the initial distribution at the time of TFT substrate formation and the temporal threshold voltage shift. The influence of such variations can be reduced by a threshold-voltage compensation operation. By the threshold-voltage compensation operation, a voltage obtained by adding a voltage corresponding to the DATA signal voltage V_{DATA} to a voltage equivalent to the threshold voltage of the corresponding drive transistor Qd is set to the storage capacitor Cs of the corresponding pixel circuit 4.

The storage capacitor Cs stores the threshold voltage of the drive transistor Qd, and also stores the DATA signal voltage V_{DATA} by which the threshold voltage of the drive transistor Qd is compensated based on the stored threshold voltage and the DATA signal voltage V_{DATA} supplied from the DATA line 7. To be more specific, the second electrode of the storage capacitor Cs is connected to a node at which the source of the drive transistor Qd (on the VSS line 82-side) and the anode 51 of the organic EL element 5 are connected. The first electrode of the storage capacitor Cs is connected to the gate of the drive transistor Qd. Furthermore, the first electrode of the storage capacitor Cs is connected to the VREF line 83 via the transistor Qref.

The transistor Qscan switches a state between the DATA line 7 for supplying the DATA signal voltage V_{DATA} and the first electrode of the storage capacitor Cs, between conducting and non-conducting states. To be more specific, the transistor Qscan is a switching transistor in which one of the drain and the source is connected to the DATA line 7, the other one of the drain and the source is connected to the first electrode of the storage capacitor Cs, and the gate is connected to the SCAN line 6, in other words, the transistor Qscan has a function of writing, to the storage capacitor Cs, a voltage corresponding to the DATA signal voltage V_{DATA} supplied via the DATA line 7.

The transistor Qref switches a state between the VREF line 83 for supplying the reference voltage V_{REF} and the first electrode of the storage capacitor Cs, between conducting and non-conducting states. To be more specific, the transistor Qref is a switching transistor in which one of the drain and the source is connected to the VREF line 83, the other one of the drain and the source is connected to the first electrode of the storage capacitor Cs, and the gate is connected to the first RESET line 92. In other words, the transistor Qref has a function of applying the reference voltage (V_{REF}) to the first electrode of the storage capacitor Cs (the gate of the drive transistor Qd).

The transistor Qrst switches a state between the second electrode of the storage capacitor Cs and the VRST line 84, between conducting and non-conducting states. To be more specific, the transistor Qrst is a switching transistor in which one of the drain and the source is connected to the VRST line 84, the other one of the drain and the source is connected to the anode 51 of the organic EL element 5 and to the second electrode of the storage capacitor Cs, and the gate is connected to the second RESET line 93. In other words, the transistor Qrst has a function of applying the reset voltage (V_{RST}) to the anode of the organic EL element 5 and the second electrode of the storage capacitor Cs (the source of the drive transistor Qd).

The transistor Qenb switches a state between the VDD line 81 and the drain of the drive transistor Qd, between conducting and non-conducting states. To be more specific, the transistor Qenb is a switching transistor in which one of the drain and the source is connected to the VDD line 81 (V_{DD}), the other one of the drain and the source is connected to the drain of the drive transistor Qd, and the gate is connected to the ENABLE line 91.

With the configuration of the pixel circuit 4 described thus far, the organic EL display apparatus 1 can compensate the temporal threshold voltage shift of the drive transistor Qd to achieve display.

It should be noted that each of the transistors Qscan, Qref, Qrst, and Qenb included in the pixel circuit 4 is described as an n-type TFT in the following. However, these transistors are not limited to the n-type TFTs. The transistors Qscan, Qref, Qrst, and Qenb may be p-type TFTs. Alternatively, the transistors Qscan, Qref, Qrst, and Qenb may be a mixture of n-type and p-type TFTs.

Moreover, potential difference between the voltage V_{REF} of the VREF line 83 and the voltage V_{RST} of the VRST line 84 is set to be larger than a maximum threshold voltage of the drive transistor Qd.

Furthermore, the voltage V_{REF} of the VREF line 83 and the voltage V_{RST} of the VRST line 84 are set as follows in a manner that a pixel current does not pass through the organic EL element 5.

Voltage V_{REF}<Voltage V_{SS}+(Forward current threshold voltage of Organic EL element 5)

(Voltage V_{REF} of VREF line 83)<Voltage V_{SS}+(Forward current threshold voltage of Organic EL element 5)+(Threshold voltage of Drive transistor Qd)

Here, the voltage V_{SS}, is a voltage of the VSS line 82 as described above.

### {Operation}

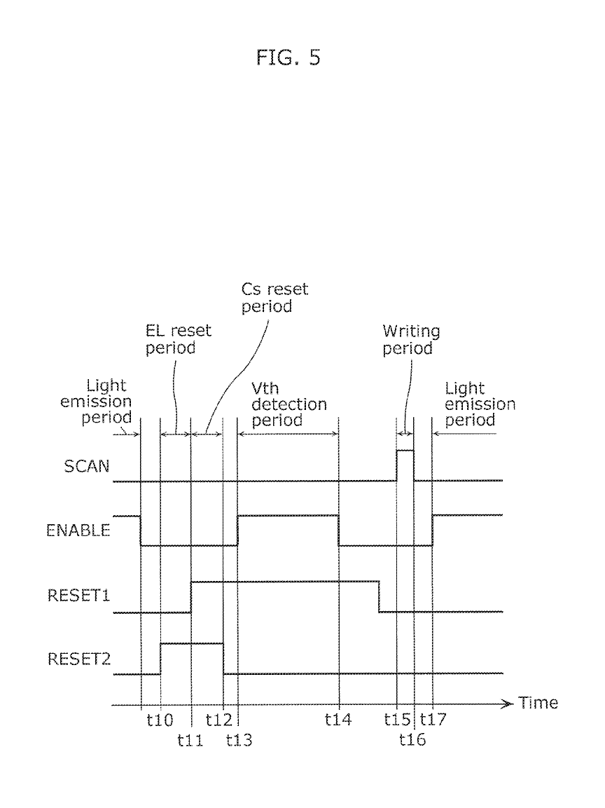

Next, an operation of the pixel circuit 4 configured as above is described with reference to FIG. 5. FIG. 5 is a timing chart showing the operation of the pixel circuit included in the organic EL display apparatus according to Embodiment 1. To be more specific, FIG. 5 shows, from top to bottom, a SCAN signal applied to the SCAN line 6, an ENABLE signal applied to the ENABLE line 91, a RESET1 signal applied to the first RESET line 92, and a RESET2 signal applied to the second RESET line 93.

### {Times t10 to t11: EL Reset Period}

During an EL reset period from a time t10 to a time t11 shown in FIG. 5, only the RESET2 signal has a HIGH voltage level and thereby only the transistor Qrst is electrically conducting.

With this, an electrical charge carried by a capacitance component CEL of the organic EL element 5 can be reset. More specifically, a source voltage of the drive transistor Qd is quickly set as the voltage V_{RST} of the VRST line 84.

### {Times t11 to t12: Cs Reset Period}

Next, at the time t11, the voltage level of the RESET1 signal changes from LOW to HIGH. In other words, the transistor Qref is brought into conduction (ON state) at the time t11. As a result of this, the electrical charge carried by the storage capacitor Cs can be reset before a time t12. More specifically, the gate voltage of the drive transistor Qd is set as the voltage V_{REF} of the VREF line 83.

In the timing chart of FIG. 5, the RESET2 signal rises at the time t10 and the RESET1 signal rises at the time t11. However, even when the RESET2 signal rises at the time t11 and the RESET1 signal rises at the time t10, the electrical charge carried by the storage capacitor Cs can be reset before the time t12.

Here, a gate-source voltage of the drive transistor Qd at the time t12 (at a finish time of the Cs reset period) needs to be set to an initial voltage that ensures an initial drain current required for the threshold voltage compensation operation performed after the Cs reset period. To be more specific, the initial voltage needs to be higher than a threshold voltage Vth of the drive transistor Qd and also needs to be a voltage that does not cause the organic EL element 5 to emit light. For this reason, the potential difference between the voltage V_{REF} of the VREF line 83 and the voltage V_{RST} of the VRST line 84 is set to be larger than the maximum threshold voltage of the drive transistor Qd. The voltage V_{REF} and the voltage V_{RST} are set in a manner that no current passes through the organic EL element 5, and thus satisfy the following two expressions, in which the forward current threshold voltage of the organic EL element 5 is represented by V_{EL}.

V_{RST}<V_{SS}+V_{EL}

V_{REF}<V_{SS}V_{EL}+Vth

After this, at the time t12, the voltage level of the RESET2 signal changes from HIGH to LOW and thereby the transistor Qrst is brought out conduction (OFF state).

### {Times t13 to t14: Vth Detection Period}

Next, at a time t13, the voltage level of the ENABLE signal changes from LOW to HIGH. In other words, the transistor Qenb is brought into conduction (ON state) at the time t13. With this, a threshold detection current i_{prog} starts passing from the drain side to the source side in the drive transistor Qd. More specifically, the storage capacitor Cs and the capacitance component CEL of the organic EL element 5, which are loads to the drive transistor Qd, start to be charged at the time t13. As the capacitance component CEL is charged in this way, the source voltage of the drive transistor Qd gradually rises. To be more specific, the source voltage of the drive transistor Qd rises until the gate-source voltage of this drive transistor Qd reaches the threshold voltage Vth of this drive transistor Qd.

After this, the voltage level of the ENABLE signal changes from HIGH to LOW at a time t14. As a result, the transistor Qenb is brought out conduction (OFF state), and supply of the threshold detection current i_{prog} is stopped.

After this, the voltage level of the RESET1 signal changes from HIGH to LOW during a period between the times t14 and t15. As a result, the transistor Qref is brought out conduction (OFF state), and the gate-source voltage of the drive transistor Qd at the time t15 is stored into the storage capacitor Cs.

In the timing chart of FIG. 5, the ENABLE signal falls at the time t14 and the RESET1 signal falls during the time between the times t14 and t15. However, even when the RESET1 signal falls at the time t14 and the ENABLE signal falls during the time between the times t14 and t15, the gate-source voltage of the drive transistor Qd at the time t15 can be stored into the storage capacitor Cs.

### {Times t15 to t16: Writing Period}

Next, at the time 15, the voltage level of the SCAN signal changes from LOW to HIGH and thereby the transistor Qscan is brought into conduction (ON state). As a result, the first electrode of the storage capacitor is applied with the DATA signal voltage V_{DATA} (the signal voltage) supplied from the DATA line 7.

After this, at the time t16, the voltage level of the SCAN signal changes from HIGH to LOW and thereby the transistor Qscan is brought out conduction (OFF state). As a result, in addition to the threshold voltage Vth of the drive transistor Qd stored during the Vth detection period, the storage capacitor Cs also stores a potential difference obtained by multiplying the potential difference between the DATA signal voltage V_{DATA} and the voltage V_{REF} of the VREF line 83 by (a capacity C_{EL} of the capacitance component CEL of the organic electrode element 5)/(the capacity C_{EL} of the organic electrode element 5+a capacity Cₛ of the storage capacitor Cs).

### {From Time T17 and Afterward: Light Emission Period}

Next, at a time t17, the voltage level of the ENABLE signal changes from LOW to HIGH and thereby the transistor Qenb is brought into conduction (ON state). As a result, the drive transistor Qd supplies the organic EL element 5 with the pixel current corresponding to the voltage stored by the storage capacitor Cs. This enables the organic EL element 5 to emit light.

As a result of the operation above, the pixel circuit 4 can emit light having luminance corresponding to the DATA signal voltage V_{DATA}.

### [Influence of Capacitance Component of Organic EL Element on Voltage of Power Supply Line (VREF Line)]

The inventors have found that when the power supply lines 8 are arranged in almost parallel to the banks 3a shown in FIG. 2, a streak pattern corresponding to the banks 3a may possibly be displayed. In view of this, the organic EL display apparatus 1 according to Embodiment 1 includes the power supply lines 8 which are arranged to cross the banks 3a as viewed from above (i.e., as viewed from the positive side of the Z-axis direction).

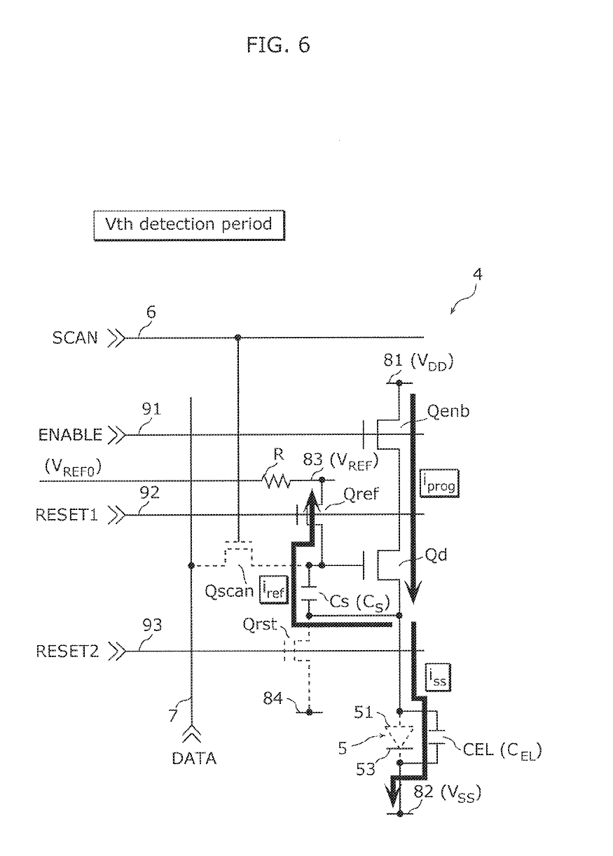

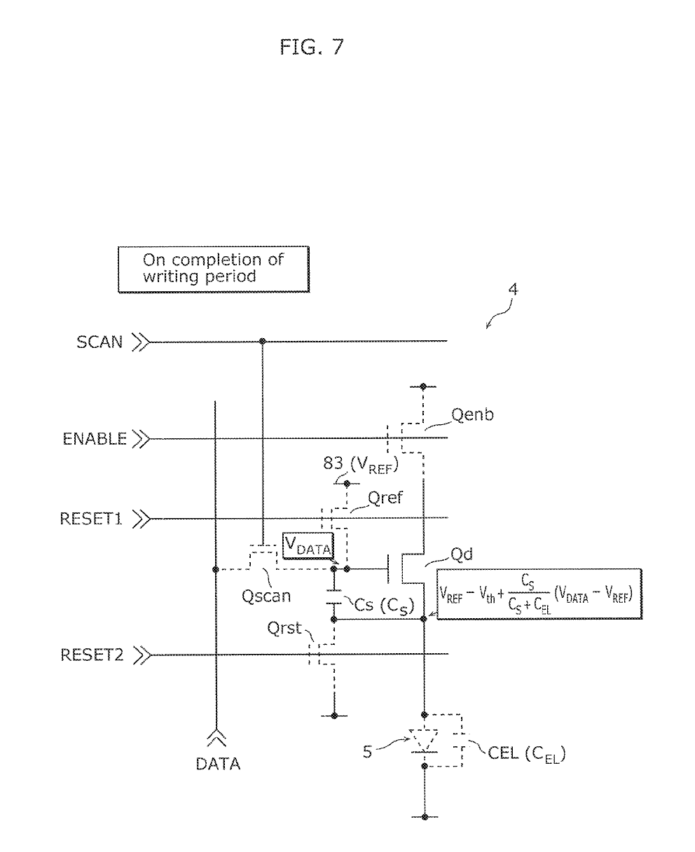

First, a finding of the inventors as a factor responsible for the aforementioned streak pattern displayed corresponding to the banks 3a is described, with reference to FIG. 6 and FIG. 7. FIG. 6 is an explanatory view showing a state of the pixel circuit 4 in the Vth detection period shown in FIG. 5. FIG. 7 is an explanatory view showing a state of the pixel circuit 4 in the light emission period shown in FIG. 5.

### {State of Pixel Circuit in Vth Detection Period}

As shown in FIG. 6, the charging of the storage capacitor Cs with the threshold detection current i_{prog} allows a current i_{ref} to flow from the source of the drive transistor Qd to the VREF line 83 via this storage capacitor Cs. Similarly, the charging of the capacitance component CEL with the threshold detection current i_{prog} allows a current i_{SS} to flow from the source of the drive transistor Qd to the VSS line 82 via this capacitance component CEL.

Here, a voltage drop (a voltage depression) due to a wiring resistance of the VREF line 83 occurs to this VREF line 83 to which the current i_{ref} flows. Such a voltage drop may possibly have an influence on a display screen of the organic EL display apparatus 1. For example, the layout of the VREF lines 83 in the organic EL display apparatus 1 is constrained by the other lines, electrodes, and so forth formed in the same layer as the VREF lines 83. On this account, the VREF line 83 has a wiring resistance with a size that should not be ignored. More specifically, when the current passes through the VREF line 83, the voltage drop (the voltage depression) of this VREF line 83 due to the wiring resistance becomes too large to be ignored and thereby may possibly have an influence on the display screen of the organic EL display apparatus 1.

To be more specific, in the Vth detection period, the voltage V_{REF} supplied to the pixel circuit 4 from the VREF line 83 is higher than a voltage V_{REF0} supplied to the VREF line 83 from a power source unit provided outside the pixel circuits 4. That is, the voltage drop occurs to the VREF line 83 in the Vth detection period. The magnitude of this voltage drop depends on the capacitance component CEL of the organic EL element 5. This is because the amount of voltage drop occurring to the VREF line 83 depends on the charging current of the capacitance component CEL having the capacity CF_{EL} in the organic EL element 5. In other words, the voltage V_{REF} has a dependence on the capacitance component CEL of the organic EL element 5.

The following describes the reason why the voltage V_{REF} has a dependence on the capacitance component CEL of the organic EL element 5, using Expressions 1 to 5.

First, assuming that the gate-source voltage of the drive transistor Qd is V_{gs} and that threshold voltage of the drive transistor Qd is Vₜₕ, the threshold detection current i_{prog} supplied by the drive transistor Qd in the Vth detection period is represented as follows.

$$\begin{matrix}[ Math . 1 ] & \\ {i}_{prog} = \frac{β}{2} {( {V}_{gs} - {V}_{th} )}^{2} & Expression 1\end{matrix}$$

Here, β is a coefficient that is determined depending on a mobility μ of the drive transistor Qd, a gate-insulating-film capacity Cox, a channel length L, and a channel width W, and is represented by Expression 2 below.

β=(W/L)·p·Cox Expression 2

Moreover, assuming that the source voltage of the drive transistor Qd is V_{S}, the threshold detection current i_{prog} is represented by Expression 3 below.

$$\begin{matrix}[ Math . 2 ] & \\ \begin{matrix}{i}_{prog} = {i}_{ref} + {i}_{ss} \\ = {i}_{ref} + {C}_{EL} \frac{d {V}_{s}}{d t}\end{matrix} & Expression 3\end{matrix}$$

More specifically, the current i_{ref} flowing from the source of the drive transistor Qd to the VREF line 83 in the Vth detection period is represented by Expression 4

$$\begin{matrix}[ Math . 3 ] & \\ {i}_{ref} = \frac{β}{2} {( {V}_{gs} - {V}_{th} )}^{2} - {C}_{EL} \frac{d {V}_{s}}{d t} & Expression 4\end{matrix}$$

More specifically, it can be understood that the current i_{ref} flowing to the VREF line 83 is influenced by the capacity C_{EL} of the capacitance component CEL of the organic electrode element 5.

Thus, assuming that a wiring resistance corresponding to the pixel 3 among the wiring resistances of the VREF line 83 is R and that the voltage supplied from outside the pixel circuits 4 to each of the VREF lines 83 is V_{REF0}, the voltage V_{REF} supplied from the VREF line 83 to the corresponding pixel circuit 4 is represented by Expression 5 below.

$$\begin{matrix}[ Math . 4 ] & \\ \begin{matrix}{V}_{REF} = {V}_{REF 0} + \sum {Ri}_{ref} \\ = {V}_{REF 0} + \sum R ( \frac{β}{2} {( {V}_{gs} - {V}_{th} )}^{2} - {C}_{EL} \frac{d {V}_{s}}{d t} )\end{matrix} & Expression 5\end{matrix}$$

More specifically, the voltage V_{REF} supplied from the VREF line 83 to the corresponding pixel circuit 4 is influenced by the capacity C_{EL} of the capacitance component CEL of the organic electrode element 5. Thus, as represented by Expression 4, the current i_{ref} flowing to the VREF line 83 is influenced by the capacity C_{EL} of the capacitance component CEL, and thereby the voltage V_{REF} is influenced by the capacity C_{EL} of the capacitance component CEL as well. In other words, the voltage V_{REF} has a dependence on the capacitance component CEL of the organic EL element 5.

Here, as described above, the source voltage V_{S} of the drive transistor Qd rises as the capacitance component CEL of the organic EL element 5 is charged in the Vth detection period. Furthermore, the voltage V_{REF}, which is the gate voltage V_{S} of the drive transistor Qd in this period, has a dependence on the capacitance component CEL of the organic EL element 5 as represented by Expression 5 above.

Thus, assuming that an elapsed time from the start time t13 of the Vth detection period is t and that the gate-source voltage of the drive transistor Qd at the start time t13 is V_{gs} (0), the gate-source voltage V_{gs} (t) of the drive transistor Qd at a time after the elapsed time t from the start time t13 of the Vth detection period is represented by Expression 6 below.

$$\begin{matrix}[ Math . 5 ] & \\ {V}_{gs} ( t ) = \frac{1}{\frac{β \cdot t}{2 ( {C}_{S} + {C}_{EL} )} + \frac{1}{{V}_{gs} ( 0 ) - {V}_{th}}} + {V}_{th} & Expression 6\end{matrix}$$

Thus, the current i_{ref} (t) flowing from the source of the drive transistor Qd to the VREF line 83 at the time after the elapsed time t from the start time t13 of the Vth detection period is represented by Expression 7 below.

$$\begin{matrix}[ Math . 6 ] & \\ \begin{matrix}{i}_{ref} ( t ) = - {C}_{s} \frac{d {V}_{gs}}{d t} \\ = \frac{2 {C}_{s} ( {C}_{s} + {C}_{EL} )}{{β ( t + \frac{2 ( {C}_{s} + {C}_{EL} )}{β ( {V}_{gs} ( 0 ) - {V}_{th} )} )}^{2}}\end{matrix} & Expression 7\end{matrix}$$

That is, the current i_{ref} represented by Expression 4 above is specifically expressed by Expression 7. To be more specific, the current i_{ref} (t) depends on the capacitance component CEL of the organic EL element 5. On this account, it can be understood, with reference to Expression 5 above, that the voltage V_{REF} supplied from the VREF line 83 to the pixel circuit 4 in the Vth detection period depends on the capacitance component CEL of the organic EL element 5 and the elapsed time from the start time of the Vth detection period.

As described above, the voltage level of the RESET1 signal changes from HIGH to LOW at the finish time of the Vth detection period (at the time t15) and thereby the transistor Qref is brought out conduction (OFF state). Thus, at the finish time, the voltage of the first electrode of the storage capacitor Cs reaches the voltage V_{REF} of the VREF line 83 at the finish time of the Vth detection period. To be more specific, the voltage of the first electrode of the storage capacitor Cs at the finish time depends on the capacitance component CEL of the organic EL element 5 and the elapsed time from the start time of the Vth detection period.

Here, when a sufficient time has elapsed from the start time of the Vth detection period, the current i_{ref} flowing to the VREF line 83 is substantially zero and thus theoretically V_{REF}=V_{REF0}. In reality, however, it is difficult to ensure the length of the Vth period in which this current i_{ref} becomes substantially zero. On this account, V_{REF}≠V_{REF0} because of the wiring resistance of the VREF line 83.

### {State of Pixel Circuit on Completion of Writing Period}

As described above, the voltage V_{REF} of the VREF line 83 at the finish time of the Vth detection period, that is, the voltage of the first electrode of the storage capacitor Cs, depends on the capacitance component CEL of the organic EL element 5 and the elapsed time from the start time of the Vth detection period. Thus, a pixel current ipix in the light emission period also depends on the capacitance component CEL and the elapsed time. To be more specific, the luminance of the organic EL element 5 depends on the capacitance component CEL and the elapsed time. The following specifically describes the reason why the luminance of the organic EL element 5 has such a dependence.

First, the state of the pixel circuit 4 on completion of the aforementioned writing period is described with reference to FIG. 7.

As shown in FIG. 7, in addition to the threshold voltage Vth of the drive transistor Qd stored during the Vth detection period, the storage capacitor Cs also stores a potential difference obtained by multiplying the potential difference between the DATA signal voltage V_{DATA} and the voltage REF of the VREF line 83 by (the capacity C_{EL} of the capacitance component CEL of the organic electrode element 5)/(the capacity C_{EL} of the organic electrode element 5+the capacity Cₛ of the storage capacitor Cs).

To be more specific, the gate voltage V_{q} and the source voltage Vₛ of the drive transistor Qd are represented by Expressions 8 and 9 below.

V_{g}=V_{DATA} Expression 8

$$\begin{matrix}[ Math . 7 ] & \\ {V}_{s} = {V}_{REF} - {V}_{th} + \frac{{C}_{S}}{{C}_{S} + {C}_{EL}} ( {V}_{DATA} - {V}_{REF} ) & Expression 9\end{matrix}$$

Thus, the gate-source voltage V_{gs} of the drive transistor Qd is represented by Expression 10 below, and thereby the pixel current iₚᵢₓ in the light emission period is represented by Expression 11.

$$\begin{matrix}[ Math . 8 ] & \\ {V}_{gs} = \frac{{C}_{EL}}{{C}_{S} + {C}_{EL}} ( {V}_{DATA} - {V}_{REF} ) + {V}_{th} & Expression 10 \\ [ Math . 9 ] & \\ {i}_{pix} = \frac{β}{2} {( \frac{{C}_{EL}}{{C}_{S} + {C}_{EL}} ( {V}_{DATA} - {V}_{REF} ) )}^{2} & Expression 11\end{matrix}$$

That is, the pixel current iₚᵢₓ passing through the organic EL element 5 in the light emission period depends on the voltage V_{REF} of the VREF line 83. To be more specific, the pixel current iₚᵢ, depends on the voltage V_{REF} of the first electrode that is the voltage before the DATA signal voltage V_{DATA} is applied to this first electrode of the storage capacitor Cs.

Here, as described above, the voltage V_{REF} of the VREF line 83 in the Vth detection period depends on the capacity C_{EL} of the capacitance component CEL of the organic EL element 5 and the elapsed time from the start time of the Vth detection period. More specifically, the voltage V_{REF} after the Vth detection period depends on the capacity C_{EL} of the capacitance component CEL of the organic EL element 5 and the length of the Vth detection period. Thus, as with the voltage V_{REF} after the Vth detection period, the pixel current iₚᵢₓ passing through the organic EL element 5 during the light emission period also depends on the capacity C_{EL} of the capacitance component CEL of the organic EL element 5 and the length of the Vth detection period. To be more specific, the luminance of the pixel 3 depends on the capacitance component CEL of the organic EL element 5 and the length of the Vth detection period. As can be understood from Expression 11, particularly in a low gradation region in which a value of V_{DATA}−V_{REF} is small, it is apparent that the display unevenness is noticeable which is caused by the variations in the voltage V_{REF} of the VREF line 83 resulting from inconsistencies in the capacity C_{EL} of the capacitance component CEL of the organic EL element 5.

The inventors have found that, although the luminance depends on the capacitance component CEL of the organic EL element 5 and the length of the Vth detection period, the capacitance component CEL of the organic EL element 5 is a main factor causing the aforementioned streak pattern corresponding to the banks 3a to be displayed. The following describes the reason why the capacitance component CEL of the organic EL element 5 causes the streak pattern to be displayed.

As shown in FIG. 2, the capacitance component CEL of the organic EL element 5 is determined depending on the thickness of the light-emitting layer 52 interposed between the anode 51 and the cathode 53 of the organic EL element 5. To be more specific, when the thickness is thicker, the capacity C_{EL} of the capacitance component CEL is greater.

Here, the light-emitting layer 52 includes the layers (the hole injection layer 521, the hole transport layer 522, the organic light-emitting layer 523, the electron transport layer 524, and the electron injection layer 525), at least one of which (the hole transport layer 522, the organic light-emitting layer 523, and the electron transport layer 524 in Embodiment 1) is formed by the wet film-forming method, such as the ink-jet method. To be more specific, at least one of the layers of the light-emitting layer 52 is formed by dropping a solution of an organic semiconductor material to a pixel row or a pixel column located between the adjacent banks 3a.

Although, in the following, the banks 3a are described as being arranged along the direction of rows of the pixels 3 (in the direction parallel to the X axis) and the light-emitting layer 52 is described as being partitioned by the banks 3a for each pixel row, the present disclosure is not limited to this. For example, the banks 3a may be arranged along the direction of columns of the pixels 3 (in the direction parallel to the Y axis) and the light-emitting layer 52 may be partitioned by the banks 3a by pixel column.

Thus, the organic EL display apparatus 1 includes a plurality of light-emitting layers in the forms of linear sections, each of which is partitioned by the two adjacent banks 3a. Such partitioned linear sections of the light-emitting layer 52 may possibly vary in thickness, depending on the amount and concentration of the organic semiconductor material solution dropped at the time of layer formation and on a drying condition. For example, when the light-emitting layer 52 is partitioned by the banks 3a by pixel row, the light-emitting layer formed in one same pixel row may be almost uniform in thickness. In this case, however, the light-emitting layers 52 formed in different pixel rows may possibly have different thicknesses. To be more specific, the pixels 3 even in the same pixel column may possibly vary in the thickness of the light-emitting layer 52.

On this account, in the pixels 3 corresponding to one of the linear sections of the partitioned light-emitting layer 52 (for example, the pixels 3 in the same pixel row), the organic EL elements 5 of these pixels 3 have the capacitance components which are substantially the same. In other words, the pixel circuits 4 of the pixels 3 corresponding to the same linear section of the light-emitting layer 52 include the capacitance components CEL having the capacities C_{EL} which are substantially the same.

On the other hand, in the pixels 3 corresponding to different ones of the linear sections of the partitioned light-emitting layer 52 (for example, the pixels 3 in the same pixel column), the organic EL elements 5 of these pixels 3 may possibly have different capacitance components. In other words, the pixel circuits 4 of the pixels 3 corresponding to the different linear sections of the light-emitting layer 52 may possibly include the capacitance components CEL having the capacities C_{EL} which are different from each other. To be more specific, the pixels 3 even in the same pixel column may possibly vary in the capacity C_{EL}.

For this reason, when the VREF lines 83 are arranged in parallel to the banks 3a, a problem may be caused as follows.

To be more specific, in the case of such a parallel arrangement, the pixels 3 connected to the VREF line 83 (for example, the pixels 3 in the same row) include the capacitance components CEL having the capacities C_{EL}, which are substantially the same. In other words, the luminance of the pixels 3 connected to the VREF line 83 depends on the capacitance components CEL having the capacities C_{EL} which are substantially the same.

Here, as described above, the pixels 3 corresponding to the different linear sections of the partitioned light-emitting layer 52 (for example, the pixels 3 in the same pixel column) may possibly include the capacitance components CEL having the capacities C_{EL} which are different from each other. Thus, the capacitance components CEL of the pixels 3 connected to one of the VREF lines 83 (for example, the pixels 3 in one of the rows) may possibly different from the capacitance components CEL of the pixels 3 connected to another one of the VREF lines 83 (for example, the pixels of another one of the rows). More specifically, the luminances of the pixels connected to one of the VREF lines 83 depend on the capacitance components CEL with one capacity C_{EL} whereas the luminances of the pixels 3 connected to another one of the VREF lines 83 depend on the capacitance components CEL with another capacity C_{EL} different from the aforementioned one capacity C_{EL}.

To be more specific, the voltage drop for each of the VREF lines in the Vth detection period depends on the capacitance components CEL of the pixels 3 connected to the VREF line 83 (for example, the pixels in the same row). Thus, the amount of voltage drop of one of the VREF lines 83 depends on the thickness of one of the linear sections of the light-emitting layer 52 partitioned by the banks 3a whereas the amount of voltage drop of another one of the VREF lines 83 depends on the thickness of another one of the linear sections of the partitioned light-emitting layer 52. Hence, the VREF lines 83 vary in the amount of voltage drop, depending on the thickness variations among the linear sections of the light-emitting layer 52.

As a result, the pixel currents iₚᵢₓ passing through the display apparatus in the light emission period also vary, depending on the thickness variations among the linear sections of the light-emitting layer 52. More specifically, particularly when the display apparatus displays a low gradation, the streak pattern corresponding to the banks 3a is displayed.

As described above, in a threshold voltage detection period of the drive transistor Qd (that is, the Vth detection period), the current i_{ref}, which is a part of the threshold detection current i_{prog} for detecting the threshold voltage, passes through the VREF line 83. Thus, when the VREF lines 83 are arranged in parallel to the banks 3a, each of the VREF lines 83 is electrically connected to the organic EL elements 5 having the same linear section among the linear sections of the partitioned light-emitting layer 52. Thus, the VREF line 83 is assumed to be connected to, as loads, the capacitance components CEL of the organic EL elements 5 having the same linear section of the light-emitting layer 52. Hence, when each of the linear sections of the light-emitting layer 52 has a different thickness, the load of the VREF line 83 depends on the thickness of the corresponding linear section of the light-emitting layer 52. As a result of this, the amount of voltage drop of the VREF line 83 depends on the thickness of the corresponding linear section of the light-emitting layer 52, and thereby the VREF lines 83 vary in the amount of voltage drop.

Here, as described above, the pixel current iₚᵢₓ passing through the pixel 3 in the light emission period depends on the voltage of the VREF line 83. On this account, the variations in the amount of voltage drop among the VREF lines 83 influence the pixel currents iₚᵢₓ passing through the pixels 3 in the light emission period. As a result, particularly for low gradation display, the pixel current iₚᵢₓ passing through the pixel 3 in the light emission period depends on the thickness of the linear section of the light-emitting layer 52 to which the VREF line 83 corresponds. More specifically, a streak pattern corresponding to the linear sections of the light-emitting layer 52 is displayed in the light emission period. In other words, the streak pattern corresponding to the banks 3a is displayed.

In this way, as a result of keen examination, the inventors have found that the streak pattern corresponding to the banks 3a is displayed when the VREF lines 83 are arranged in parallel to the banks 3a.

In view of this, the organic: EL display apparatus 1 according to Embodiment 1 include the power supply lines 8 which are arranged to cross the banks 3a to reduce such a streak pattern displayed corresponding to the banks 3a. To be more specific, each of the VREF lines 83, which are the power supply lines 8, is arranged to cross the banks 3a.

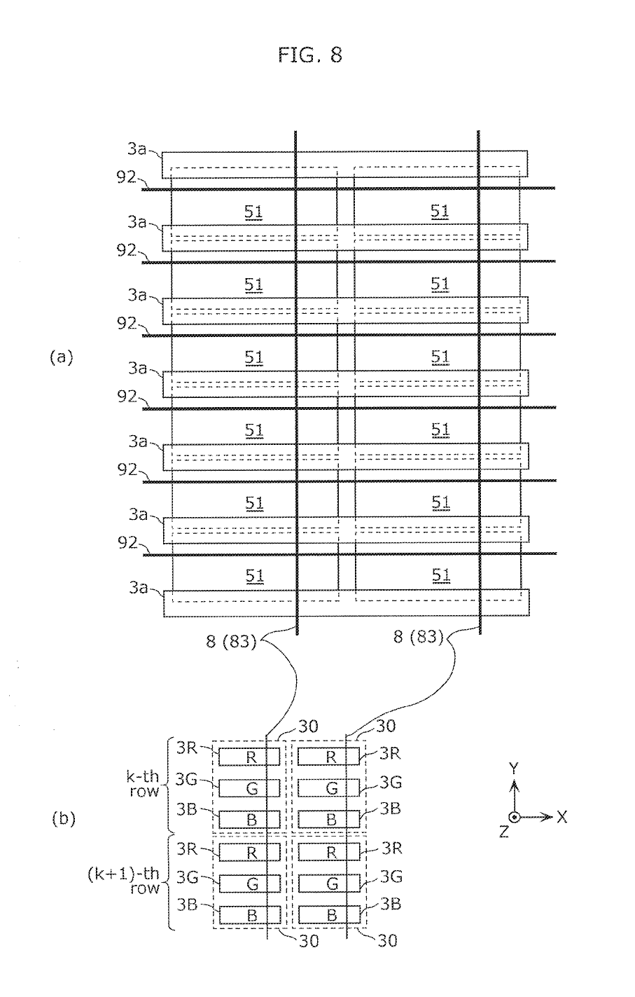

The following describes the arrangement of the VREF lines 83, which are the power supply lines 8 in Embodiment 1, with reference to FIG. 8. FIG. 8 is a diagram showing the arrangement of the power supply lines 8 (the VREF lines 83) and the banks 3a in the organic EL display apparatus 1 according to Embodiment 1. To be more specific, (a) of FIG. 8 is an enlarged top view of a part of the organic EL display apparatus 1, and (b) of FIG. 8 is a schematic diagram showing an arrangement of the pixels 3 corresponding to (a) of FIG. 8. It should be noted that although (a) of FIG. 8 is a top view of the organic EL display apparatus 1 viewed from the positive side of the Z-axis direction, the structural elements other than the banks 3a, the anodes 51, the power supply lines 8 (the VREF lines 83), and the first RESET lines 92 are not illustrated. Note also that the power supply lines 8 (the VREF lines 83) and the first RESET lines 92 are shown in a manner that the banks 3a and the anodes 51 are drawn in perspective.

As shown in (b) of FIG. 8, pixels 30, each of which includes pixels 3R, 3G, and 3B corresponding to the three colors (red, green, and blue) are shown in a matrix with two rows and two columns. The pixels 3R, 3G, and 3B are divided by color by the banks 3a.

The first RESET lines 92 are arranged, for example, in parallel to the banks 3a, and supply the RESET1 signals to the pixels 3 (the pixels 3R, 3G, and 3B). It should be noted that the first RESET lines 92 may be bound outside the pixels 3, for each of the pixels 30 including the pixels 3R, 3G, and 3B.

Here, each of the VREF lines 83 is arranged to cross the banks 3a. To be more specific, the amount of voltage drop of one of the VREF lines 83 depends on the thicknesses of the linear sections of the light-emitting layer 52 partitioned by the banks 3a. Similarly, the amount of voltage drop of another one of the VREF lines 83 depends on the thicknesses of the linear sections of the light-emitting layer 52 partitioned by the banks 3a. Therefore, the VREF lines 83 are less likely to vary in the amount of voltage drop.

As a result, the pixel currents iₚᵢₓ flowing in the light emission period are also less likely to have variations that depend on the thicknesses of the linear sections of the partitioned light-emitting layer 52. Hence, according to the organic EL display apparatus 1 in Embodiment 1, the streak pattern corresponding to the banks 3a can be reduced.

To be more specific, when each of the VREF lines 83 is arranged to cross the banks 3a, the VREF line 83 is electrically connected to the organic EL elements 5 having the different linear sections among the linear sections of the light-emitting layer 52. Thus, the VREF line 83 is assumed to be connected to, as loads, the capacitance components CEL of the organic EL elements 5 having the different linear sections of the light-emitting layer 52. Hence, even when the thickness is different for each of the linear sections of the light-emitting layer 52, the load of the VREF line 83 is less likely to depend on the thickness of the specific linear section of the light-emitting layer 52. As a result of this, the VREF lines 83 are less likely to vary in the amount of voltage drop. This can reduce the streak pattern corresponding to the banks 3a that is displayed in the light emission period. That is, the organic EL display apparatus 1 according to Embodiment 1 can reduce the display unevenness.

To be more specific, when the DATA signal voltages V_{DATA} with the same luminance are applied to the red pixels 3R located in the pixels 30 in a k-th row (where k is a natural number) and to the red pixels 3R located in the pixels 30 in a (k+1)-th row, the organic EL display apparatus 1 according to Embodiment enables the red pixels 3R in the k-th row and the red pixels 3R in the (k+1)-th row to emit light of almost the same luminance.

On the other hand, when each of the VREF lines 83 is arranged in parallel to the banks 3a and even the DATA signal voltages V_{DATA} with the same luminance are applied to the red pixels 3R located in the pixels 30 in the k-th row and to the red pixels 3R located in the pixels 30 in the (k+1)-th row, the red pixels 3R in the k-th row and the red pixels 3R in the (k+1)-th row may possibly emit light of different luminances. In other words, the streak pattern corresponding to the banks 3 may possibly be displayed.

### CONCLUSION

As described above, the organic EL display apparatus 1 according to Embodiment has the pixels 3 and includes the following: the thin-film transistor array device 2; the light-emitting layer 52 which is provided above the thin-film transistor array device 2; the banks 3a which partition the light-emitting layer 52 into the linear sections; and the power supply lines 8 which are provided for the thin-film transistor array device 2 and supply the predetermined voltage to the pixels 3. Each of the pixels 3 has the organic electrode element 5 which includes a part of the light-emitting layer 52 partitioned into the linear sections and emits light corresponding to the supplied current, the drive transistor Qd which controls the current to be supplied to the organic EL element 5, and the storage capacitor Cs which stores the gate-source voltage of the drive transistor Qd. Each of the VREF lines 83 (one aspect of the power supply lines 8 according to the present disclosure) is arranged to cross the banks 3a as viewed from above.

Such an arrangement, in which each of the VREF lines 83 crosses the banks 3a as viewed from above, allows the VREF line 83 to be electrically connected to the organic EL elements 5 having the different linear sections among the linear sections of the light-emitting layer 52 when the transistor Qref arranged between the VREF line 83 and the gate of the drive transistor Qd is conducting. Thus, the VREF line 83 is assumed to be connected to, as loads, the capacitance components CEL of the organic EL elements 5 having the different linear sections of the light-emitting layer 52. Hence, even when the thickness is different for each of the linear sections of the light-emitting layer 52, the load of the VREF line 83 is less likely to depend on the thickness of the specific linear section of the light-emitting layer 52. As a result of this, the VREF lines 83 are less likely to vary in the amount of voltage drop. Here, when the VREF lines 83 vary in the amount of voltage drop, the streak pattern corresponding to the banks 3a may possibly be displayed. However, according to the organic EL display apparatus 1 according to Embodiment 1, the VREF lines 83 are less likely to vary in the amount of voltage drop and this can reduce the streak pattern to be displayed. That is, the display unevenness can be reduced.

To be more specific, the first electrode of the storage capacitor Cs is electrically connected to the gate of the drive transistor Qd, and the second electrode of the storage capacitor Cs is electrically connected to the source of the drive transistor Qd and to the anode 51 of the organic electrode element 5. The organic EL display apparatus 1 includes the following: the VREF lines 83 each for supplying the reference voltage V_{REF}, which is the reference voltage to detect the threshold voltage for each of the pixels 3; the VDD lines 81 each electrically connected to the drain of the drive transistor Qd and each for supplying a current to cause the organic EL element 5 of the pixel 3 to emit light. Each of the pixels 3 further includes the transistor Qref that switches the state between the VREF line 83 and the first electrode of the storage capacitor Cs, between conducting and non-conducting states.

Here, when the threshold voltage of the drive transistor Qd is detected, the current i_{ref}, which is a part of the threshold detection current for detecting the threshold voltage, passes through the VREF line 83. This causes a voltage drop. The voltage drop caused to the VREF line 83 influences the pixel current iₚᵢₓ which passes through the pixel 3 during light emission. Thus, the variations in the amount of voltage drop among the VREF lines 83 cause the display unevenness. However, the arrangement in which each of the VREF lines 83 crosses the banks 3a can reduce the variations in the amount of voltage drop among the VREF lines 83. Hence, the display unevenness can be reduced.

For example, the organic EL element 5 further includes the anode 51 and the cathode 53 which are provided above the thin-film transistor array device 2 and disposed opposite to each other via a part of the light-emitting layer 52 partitioned into the linear sections. The light-emitting layer 52 includes the hole injection layer 521, the hole transport layer 522, the organic light-emitting layer 523, the electron transport layer 524, and the electron injection layer 525 which are laminated from the anode side in the stated order.

Furthermore, at least one of the hole injection layer 521, the hole transport layer 522, the organic light-emitting layer 523, the electron transport layer 524, and the electron injection layer 525 may be formed by the printing method, or more specifically, by the wet film-forming method, such as the ink-jet method.

Here, the thickness of the layer formed by the printing method may possibly be different for each of the linear sections of the light-emitting layer 52. To be more specific, when at least one of the hole injection layer 521, the hole transport layer 522, the organic light-emitting layer 523, the electron transport layer 524, and the electron injection layer 525 included in the light-emitting layer 52 is formed by the printing method, the thickness of the light-emitting layer 52 may possibly be different for each of the linear sections of the light-emitting layer 52. However, the arrangement in which each of the VREF lines 83 crosses the banks 3a can reduce the display unevenness even when at least one of these layers included in the light-emitting layer 52 is formed by the printing method.

Moreover, for example, each of the VREF lines 83 may be arranged to be orthogonal to the banks 3a.

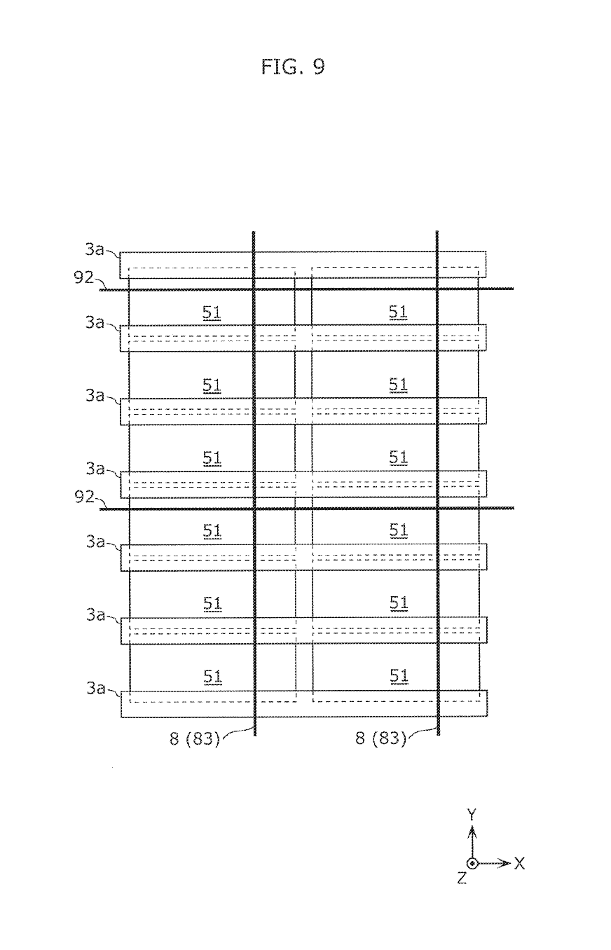

In the above description, the first RESET line 92 is arranged corresponding to each of the colors, or more specifically, for each of the pixels 3R, 3G, and 3B. However, the first RESET line 92 may be arranged as shown in FIG. 9. FIG. 9 is a diagram showing another example of the arrangement of the first RESET lines 92 in the organic EL display apparatus 1 according to Embodiment 1. To be more specific, FIG. 9 is an enlarged top view of a part of another example of the organic: EL display apparatus 1.

As shown in FIG. 9, the first RESET line 92 may be arranged corresponding to the pixel 30 including the pixels of the colors shown in (b) of FIG. 8 (that is, the pixels 3R, 3G, and 3B). In such an arrangement, each of the first RESET lines 92 is divided into a plurality of lines in the pixel 30 to be connected to each of the pixels of the colors (that is, the pixels 3R, 3G, and 35).

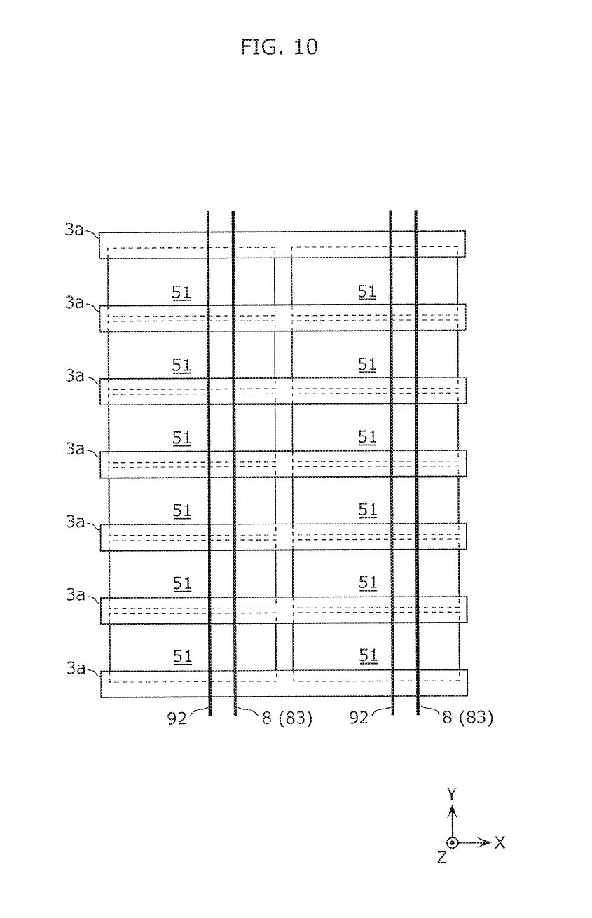

Furthermore, the first RESET lines 92 are arranged in parallel to the banks 3a as viewed from above in the above description. However, the first RESET lines 92 may be arranged as shown in FIG. 10. FIG. 10 is a diagram showing another example of the arrangement of the first RESET lines 92 in the organic EL display apparatus 1 according to Embodiment 1. To be more specific, FIG. 10 is an enlarged top view of a part of another example of the organic EL display apparatus 1.

As shown in FIG. 10, the first RESET lines 92 may be arranged to cross the banks 3a as viewed from above. To be more specific, the first RESET lines 92 may be arranged to be orthogonal to the banks 3a as viewed from above. That is, although the first RESET line 92 is arranged for each of the pixels 3R, 3G, and 3B in the above description, the first RESET line 92 may be arranged corresponding to all the pixels 3R, 3G, and 35.

### Modification of Embodiment 1

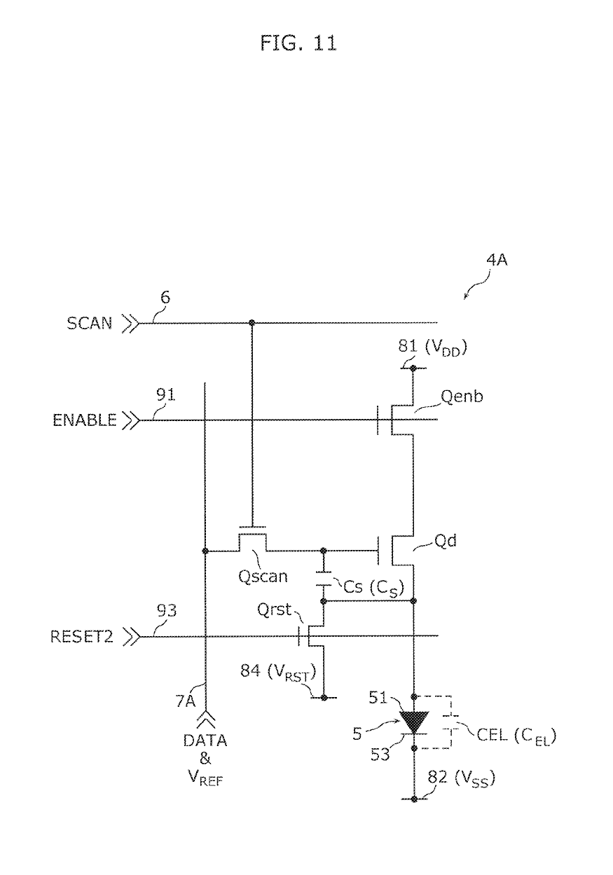

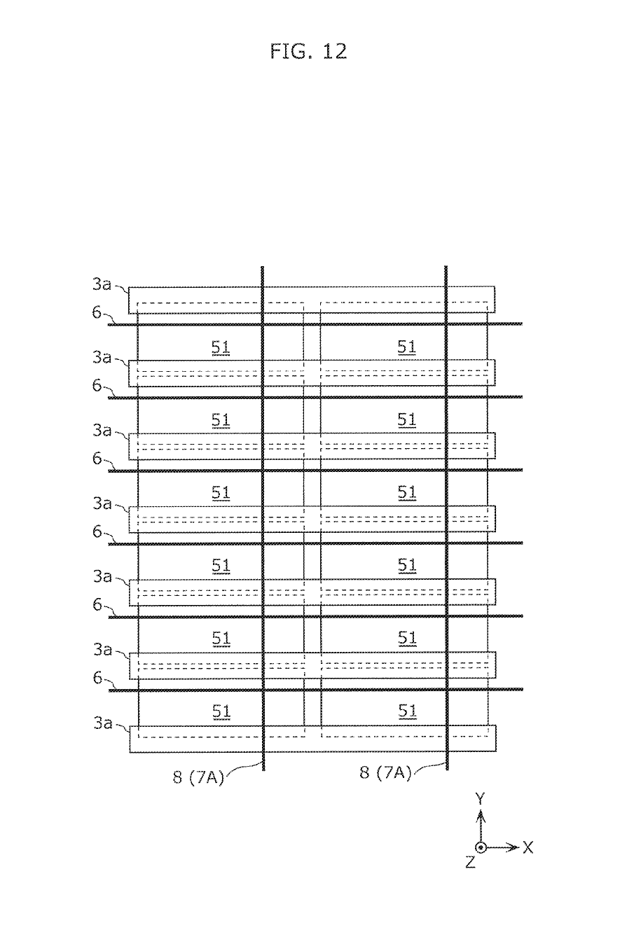

Next, Modification of Embodiment 1 above is described below. An organic EL display apparatus according to Modification is almost the same as the organic EL display apparatus 1 according to Embodiment described above, except that the organic EL display apparatus according to Modification includes, as power supply lines for supplying a reference voltage V_{REF}, a plurality of DATA lines (signal lines) each for supplying a DATA signal voltage V_{DATA} (a signal voltage) that determines the luminance of pixels 3 and supplying the reference voltage V_{REF}. More specifically, the organic EL display apparatus according to Modification is different in that the DATA lines substitute for the VREF lines 83 used as the power supply lines for supplying the reference voltage V_{REF}. In other words, the organic EL display apparatus according to Modification is different in that the DATA lines are used as the power supply lines for supplying the reference voltage V_{REF}. The following describes mainly the differences between the organic EL display apparatus according to Modification and the organic EL display apparatus 1 according to Embodiment 1, with reference to FIG. 11 and FIG. 12.

FIG. 11 is an electric circuit diagram showing a configuration of a pixel circuit included in the organic EL display apparatus according to Modification of Embodiment 1.

As shown in FIG. 11, in comparison with the pixel circuit 4 in Embodiment 1 above, a pixel circuit 4A in Modification is provided with, as the power supply line for supplying the reference voltage V_{REF}, a DATA line 7A for supplying the DATA signal voltage V_{DATA} and the reference voltage V_{REF}. This DATA line 7A is supplied with the DATA signal voltage V_{DATA} and the reference voltage V_{REF} on a time-sharing basis, for example. To be more specific, for example, the voltage level of a SCAN signal for the corresponding row in a Vth detection period becomes Hi while the DATA line 7A is being supplied with the reference voltage V_{REF}, and the voltage level of the SCAN signal for the corresponding row in a data writing period becomes Low while the DATA line 7A is being supplied with the DATA signal voltage V_{DATA}. That is, the pixel circuit 4A in Modification substitutes the DATA line 7A for the power supply line for supplying the reference voltage V_{REF}.

Thus, in comparison with the pixel circuit 4 in Embodiment 1 that is provided with both the DATA line 7 for supplying the DATA signal voltage V_{DATA} and the VREF line 83 for supplying the reference voltage V_{REF} the number of wiring lines can be reduced according to the pixel circuit 4A in Modification. Thus, the layout design can be easily created.

As is the case with each of the VREF lines 83 in Embodiment 1, each of the DATA lines 7A used as the power supply line for supplying the reference voltage V_{REF} in Modification is arranged to cross the banks 3a as viewed from above. With this, the organic EL display apparatus according to Modification can achieve the same advantageous effects as in Embodiment 1 above.

FIG. 12 is a diagram showing an arrangement of the power supply lines 8 (the DATA lines 7A) and the banks 3a in the organic EL display apparatus according to Modification of Embodiment 1. To be more specific, FIG. 12 is an enlarged top view of a part of the organic EL display apparatus 1. It should be noted that, in FIG. 12, the structural elements other than the banks 3a, the anodes 51, the power supply lines 8 (the DATA lines 7A), and the SCAN lines 6 also having the functions of the first RESET lines are not illustrated. Note also that the power supply lines 8 (the DATA lines 7A) and the SCAN lines 6 are shown in a manner that the banks 3a and the anodes 51 are drawn in perspective.

As shown in FIG. 12, each of the DATA lines 7A is arranged to cross the banks 3a. To be more specific, the amount of voltage drop of one of the DATA lines 7A depends on the thicknesses of the linear sections of the light-emitting layer 52 partitioned by the banks 3a. Similarly, the amount of voltage drop of another one of the DATA lines 7A depends on the thicknesses of the linear sections of the ht-emitting layer 52 partitioned by the banks 3a. Therefore, the DATA lines 7A are less likely to vary in the amount of voltage drop.

As a result, also according to the organic EL display apparatus according to Modification as is the case with the organic EL display apparatus 1 according to Embodiment 1, the pixel currents iₚᵢₓ flowing in the light emission period are also less likely to have variations that depend on the thicknesses of the linear sections of the partitioned light-emitting layer 52. Hence, according to the organic EL display apparatus in Modification of Embodiment 1, the streak pattern corresponding to the banks 3a can be reduced.

As described thus far, the organic EL display apparatus according to Modification of Embodiment 1 includes, as the power supply lines for supplying the reference voltage V_{REF}, the DATA lines 7A each for supplying the DATA signal voltage V_{DATA} that determines the luminance of the pixels 3 and supplying the reference voltage V_{REF}. Here, each of the DATA lines 7A is arranged to cross the banks 3a as viewed from above. With this, the organic EL display apparatus according to Modification of Embodiment 1 can achieve the same advantageous effects as the organic EL display apparatus 1 according to Embodiment 1.

Furthermore, the DATA lines 7A substitute for the power supply lines 8 for supplying the reference voltage V_{REF}, and thereby the number of wiring lines can be reduced. Thus, the layout design can be easily created.

### Embodiment 2

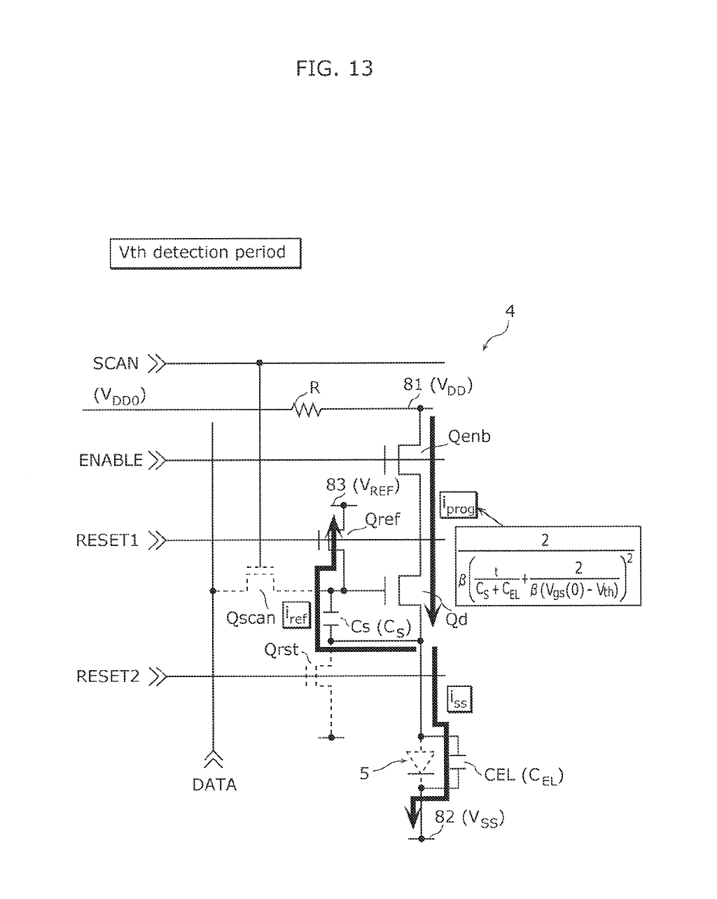

Next, Embodiment 2 is described below. An organic EL display apparatus according to Embodiment 2 is almost the same as the organic EL display apparatus 1 according to Embodiment 1 described above, except that the organic EL display apparatus according to Embodiment 2 includes VDD lines 81 in place of the VREF lines 83, as power supply lines 8 arranged to cross banks 3a as viewed from above. The following describes the organic EL display apparatus according to Embodiment 2, with reference to FIG. 13 to FIG. 15.

### [Influence of Capacitance Component of Organic EL Element on Voltage of Power Supply Line (VDD Line)]

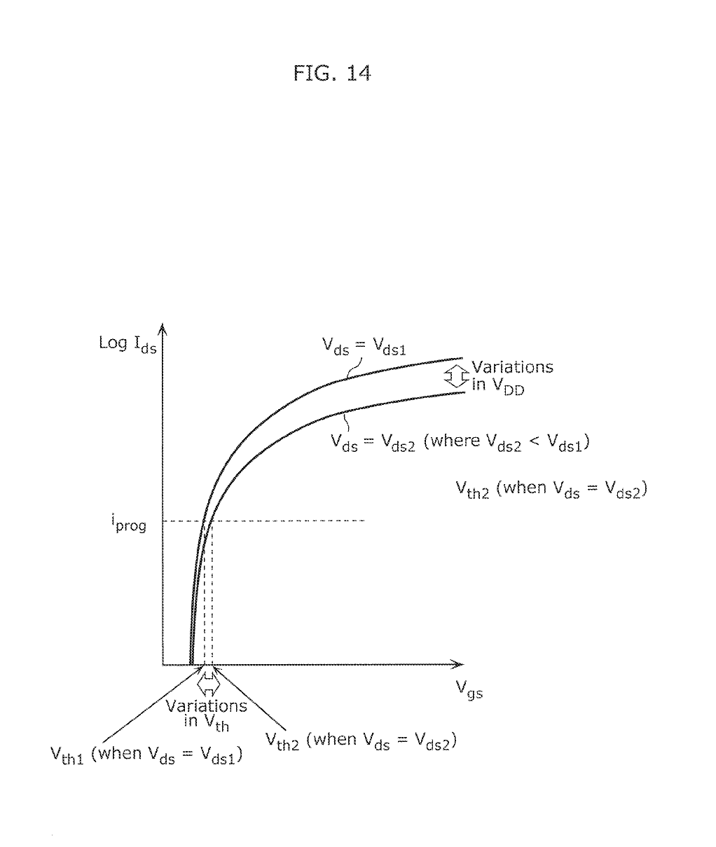

First, a further finding of the inventors as a factor responsible for the aforementioned streak pattern displayed corresponding to the banks 3a is described, with reference to FIG. 13 and FIG. 14.

### {State of Pixel Circuit in Vth Detection Period}

FIG. 13 is an explanatory view showing a state of a pixel circuit 4 in a Vth detection period shown in FIG. 5, according to Embodiment 2.

As shown in FIG. 13 and also described in Embodiment 1, the charging of a storage capacitor Cs with a threshold detection current i_{prog} allows a current i_{ref} to flow from a source of a drive transistor Qd to the VREF line 83 via this storage capacitor Cs. Similarly, the charging of a capacitance component CEL with the threshold detection current i_{prog} allows a current iₛₛ to flow from the source of the drive transistor Qd to the VSS line 82 via this capacitance component CEL.

Here, a voltage drop (a voltage depression) due to a wiring resistance of the VDD line 81 occurs to this VDD line 81 from which the current i_{prog} flows. Such a voltage drop may possibly have an influence on a display screen of the organic EL display apparatus. For example, the layout of the VDD lines 81 in the organic EL display apparatus is constrained by the other lines, electrodes, and so forth formed in the same layer as the VDD lines 81. On this account, the VDD line 81 has a wiring resistance with a size that should not be ignored. More specifically, when the current passes through the VDD line 81, the voltage drop (the voltage depression) of this VDD line 81 due to the wiring resistance becomes too large to be ignored and thereby may possibly have an influence on the display screen of the organic EL display apparatus.

To be more specific, in the Vth detection period, a voltage V_{DD} supplied to the pixel circuit 4 from the VDD line 81 is lower than a voltage V_{DD0} supplied to the VDD line 81 from a power source unit provided outside the pixel circuits 4. That is, the voltage drop occurs to the VDD line 81 in the Vth detection period. The magnitude of this voltage drop depends on the capacitance component CEL of the organic EL element 5. This is because the amount of voltage drop occurring to the VDD line 81 depends on the charging current of the capacitance component CEL having the capacity C_{EL} in the organic EL element 5. In other words, the voltage V_{DD} has a dependence on the capacitance component CEL of the organic EL element 5.

The following describes the reason why the voltage V_{DD} has a dependence on the capacitance component CEL of the organic EL element 5, using Expressions 12 to 16.

First, assuming that an elapsed time from a start time t13 of the Vth detection period is t, that a gate-source voltage of the drive transistor Qd at the time after the elapsed time t from the start time t13 is V_{gs} (t), and that a threshold voltage of the drive transistor Qd is Vₜₕ, the current i_{prog} (t) at the time after the elapsed time t from the start time t13 of the Vth detection period is represented by Expression 12 below.

$$\begin{matrix}[ Math . 10 ] & \\ {i}_{prog} ( t ) = \frac{β}{2} {( {V}_{gs} ( t ) - {V}_{th} )}^{2} & Expression 12\end{matrix}$$

Moreover, as described in Embodiment 1, assuming that the elapsed time from the start time t13 of the Vth detection period is t and that the gate-source voltage of the drive transistor Qd at the start time t13 is V_{gs} (0), the gate-source voltage V_{gs} (t) of the drive transistor Qd at the time after the elapsed time t from the start time t13 of the Vth detection period is represented by Expression 13 below.

$$\begin{matrix}[ Math . 11 ] & \\ {V}_{gs} ( t ) = \frac{1}{\frac{β \cdot t}{2 ( {C}_{S} + {C}_{EL} )} + \frac{1}{{V}_{gs} ( 0 ) - {V}_{th}}} + {V}_{th} & Expression 13\end{matrix}$$

Thus, by substitution of Expression 13 into Expression 12, i_{prog} (1) is represented by Expression 14 below.

$$\begin{matrix}[ Math . 12 ] & \\ \begin{matrix}{i}_{prog} ( t ) = \frac{{( {C}_{s} + {C}_{EL} )}^{2}}{{β ( t + \frac{2 ( {C}_{s} + {C}_{EL} )}{β ( {V}_{gs} ( 0 ) - {V}_{th} )} )}^{2}} \\ = \frac{2}{{β ( \frac{t}{{C}_{S} + {C}_{EL}} + \frac{2}{β ( {V}_{gs} ( 0 ) - {V}_{th} )} )}^{2}}\end{matrix} & Expression 14\end{matrix}$$

Furthermore, assuming that a wiring resistance corresponding to the pixel 3 among the wiring resistances of the VDD line 81 is R and that the voltage supplied from outside the pixel circuits 4 to each of the VREF lines 81 is V_{DD0}, the voltage V_{DD} supplied from the VDD line 81 to the corresponding pixel circuit 4 is represented by Expression 5 below.

[Math. 13]

V_{DD}=V_{DD0}−ΣRi_{prog} Expression 15

Thus, by substitution of Expression 14 into Expression 15, V_{vDD} at the time after the elapsed time t from the start time t13 of the Vth detection period is represented by Expression 16 below.

$$\begin{matrix} [ Math . 14 ] & \\ {V}_{VDD} = {V}_{VDD 0} - \sum R \frac{2}{{β ( \frac{t}{{C}_{S} + {C}_{EL}} + \frac{2}{β ( {V}_{gs} ( 0 ) - {V}_{th} )} )}^{2}} & Expression 16\end{matrix}$$

To be more specific, the voltage of the VDD line 81 in the Vth detection period depends on the capacitance component CEL of the organic EL element 5 and the elapsed time from the start time of the Vth detection period.

Here, when a sufficient time has elapsed from the start time of the Vth detection period, the current i_{prog} flowing from the VDD line 81 is substantially zero and thus theoretically V_{DD}=V_{DD0}. In reality, however, it is difficult to ensure the length of the Vth period in which this current i_{prog} becomes substantially zero. On this account, V_{REF}≠V_{REF0} because of the wiring resistance of the VDD line 81.

As described above, the voltage V_{VDD} of the VDD line 81 in the Vth detection period depends on the capacitance component CEL of the organic EL element 5 and the elapsed time from the start time of the Vth detection period. Thus, the threshold voltage of the drive transistor Qd detected in this period also depends on the capacitance component CEL and the elapsed time. In other words, the drive transistor Qd to be detected depends on the capacitance component CEL and the elapsed time. The following specifically describes the reason why the threshold voltage of the drive transistor Qd has such a dependence.

FIG. 14 is a graph showing I-V characteristics of the drive transistor Qd according to Embodiment 2. To be more specific, FIG. 14 shows a drain current I_{ds} with respect to the gate-source voltage V_{gs} of the drive transistor Qd in the cases where a drain-source voltage V_{ds} of the drive transistor Qd is V_{d51} and where the drain-source voltage V_{ds} is V_{ds2} (note that V_{ds2}<V_{ds1}).

As shown in FIG. 14, the drain current I_{ds} of the drive transistor Qd depends on not only the date-source voltage V_{gs} of the drive transistor Qd, but also on the drain-source voltage V_{ds} of the drive transistor Qd.

Here, a threshold voltage Vₜₕ of the drive transistor Qd, which is the voltage stored by the storage capacitor Cs after the Vth detection period (after the time t15 in FIG. 5), is the gate-source voltage V_{gs} of the drive transistor Qd at the finish time of the Vth detection period (at the time t15 in FIG. 5). In other words, the threshold voltage Vₜₕ detected in the Vth detection period depends on the drain-source voltage V_{ds} of the drive transistor Qd.

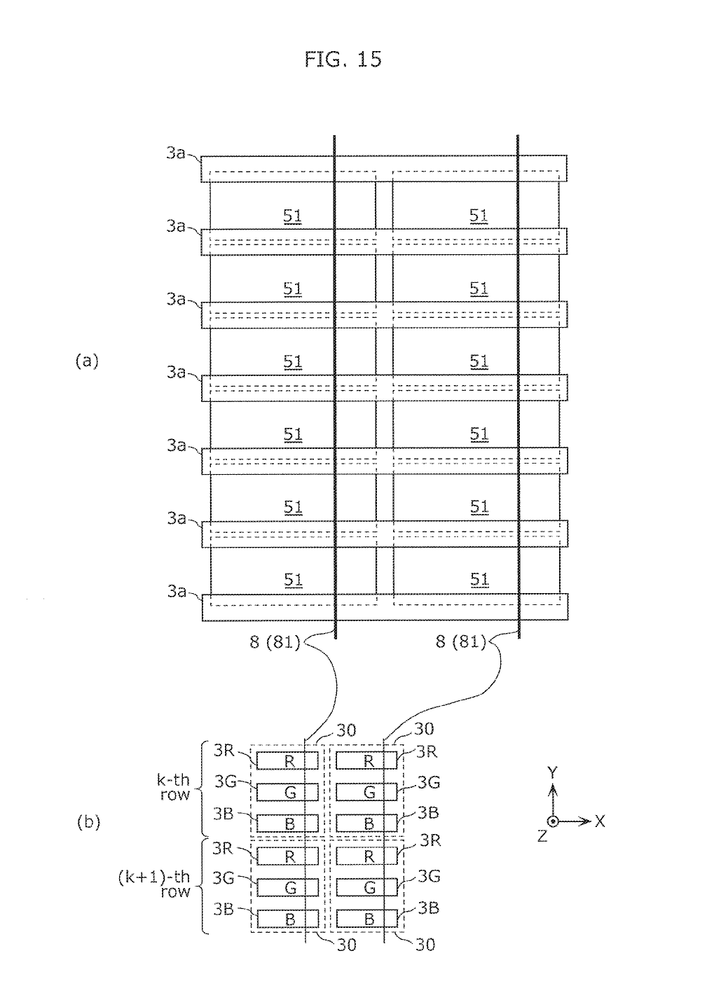

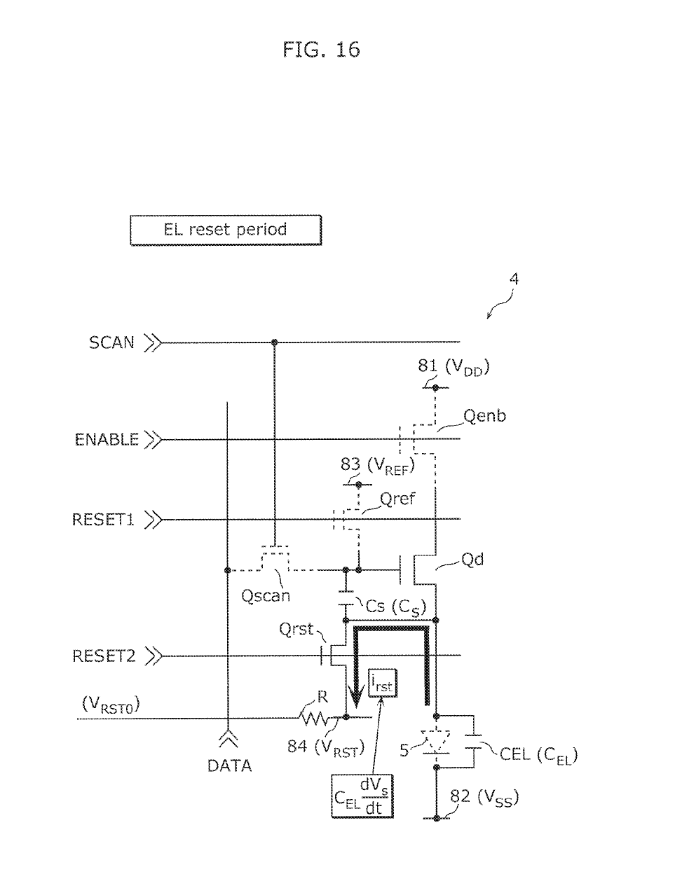

Moreover, as described above, the voltage V_{DD} of the VDD line 81 in the Vth detection depends on the capacity C_{EL} of the capacitance component CEL of the organic EL element 5 and the elapsed time from the start time of the Vth detection period. More specifically, the voltage V_{DD} at the finish time of the Vth detection period (at the time t15 in FIG. 15) depends on the capacity C_{EL} of the capacitance component CEL of the organic EL element 5 and the length of the Vth detection period. Thus, as with the voltage V_{DD} at the finish time, the drain-source voltage V_{ds} of the drive transistor Qd at the finish time also depends on the capacity C_{EL} of the capacitance component CEL of the organic EL element 5 and the length of the Vth detection period.

In this way, the threshold voltage Vₜₕ detected in the Vth detection period depends on the drain-source voltage V_{ds} of the drive transistor Qd, and this drain-source voltage V_{ds} depends on the capacity C_{EL} of the capacitance component CEL of the organic EL element 5 and the length of the Vth detection period. Thus, it can be understood that the threshold voltage Vₜₕ, detected in the Vth detection period depends on the capacity C_{EL} of the capacitance component CEL of the organic EL element 5 and the length of the Vth detection period.

The inventors have found that, between the capacitance component CEL of the organic EL element 5 and the length of the Vth detection period that influence the threshold voltage Vₜₕ, the capacitance component CEL of the organic EL element 5 is a main factor responsible for the aforementioned streak pattern displayed corresponding to the banks 3a. The following describes the reason why the capacitance component CEL of the organic EL element 5 causes the streak pattern to be displayed.

As described in Embodiment 1, the capacitance component CEL of the organic EL element 5 is determined by the thickness of the light-emitting layer 52 interposed between the anode 51 and the cathode 53 of this organic EL element 5. The thickness of the light-emitting layer 52 may possibly be different for each of linear sections of the light-emitting layer 52 partitioned by the banks 3a. Thus, the capacities C_{EL} of the capacitance components CEL included in the pixel circuits 4 of the pixels 3 corresponding to the same linear section of the light-emitting layer 52 are substantially the same. However, the capacities C_{EL} of the capacitance components CEL included in the pixel circuits 4 of the pixels 3 corresponding to different linear sections of the light-emitting layer 52 may possibly be different from each other.

For this reason, when the VDD lines 81 are arranged in parallel to the banks 3a, the following problem is caused as in the case where the VREF lines 83 are arranged in parallel to the banks 3a as described in Embodiment 1. That is, the VDD lines 81 vary in the amount of voltage drop.

As described above, the threshold voltage Vₜₕ detected in the Vth detection period depends on the drain-source voltage V_{ds} of the drive transistor Qd. More specifically, the threshold voltage Vₜₕ of the drive transistor Qd depends on the voltage V_{DD} of the VDD line 81 connected to the pixel circuit 4 including this drive transistor Qd. On this account, the variations in the amount of voltage drop among the VDD lines 81 influence the threshold voltage Vₜₕ to be detected. As a result of the arrangement in which the VDD lines 81 are parallel to the banks 3a, the streak pattern corresponding to the linear sections of the light-emitting layer 52 is displayed.

In view of this, the organic EL display apparatus according to Embodiment 2 include the power supply lines 8 which are arranged to cross the banks 3a to reduce such a streak pattern displayed corresponding to the banks 3a. To be more specific, each of the VDD lines 81, which are the power supply lines 8, is arranged to cross the banks 3a.

The following describes the arrangement of the VDD lines 81, which are the power supply lines 8 in Embodiment 2, with reference to FIG. 15. FIG. 15 is a diagram showing the arrangement of the power supply lines 8 (the VDD lines 81) and the banks 3a in the organic EL display apparatus according to Embodiment 2. To be more specific, (a) of FIG. 15 is an enlarged top view of a part of the organic EL display apparatus, and (b) of FIG. 15 is a schematic diagram showing an arrangement of the pixels 3 corresponding to (a) of FIG. 15. It should be noted that although (a) of FIG. 15 is a top view of the organic EL display apparatus viewed from the positive side of the Z-axis direction, the structural elements other than the banks 3a, the anodes 51, and the power supply lines 8 (the VDD lines 81), are not illustrated. Note also that the power supply lines 8 (the VREF lines 83) are shown in a manner that the banks 3a and the anodes 51 are drawn in perspective.

As shown in (b) of FIG. 15, pixels 30, each of which includes pixels 3R, 3G, and 3B corresponding to the three colors (red, green, and blue) are shown in a matrix with two rows and two columns. The pixels 3R, 3G, and 3B are divided by color by the banks 3a.

Here, each of the VDD lines 81 is arranged to cross the banks 3a. To be more specific, the amount of voltage drop of one of the VDD lines 81 depends on the thicknesses of the linear sections of the light-emitting layer 52 partitioned by the banks 3a. Similarly, the amount of voltage drop of another one of the VDD lines 81 depends on the thicknesses of the linear sections of the light-emitting layer 52 partitioned by the banks 3a. Therefore, the VDD lines 81 are less likely to vary in the amount of voltage drop.

As a result, the threshold voltages Vₜₕ detected in the Vth detection period are also less likely to have variations that depend on the thicknesses of the linear sections of the light-emitting layer 52. Hence, the organic EL display apparatus according to Embodiment 2 can achieve the same advantageous effects as in Embodiment 1 above.

To be more specific, such an arrangement, in which each of the VDD lines 81 crosses the banks 3a, allows the VDD line 81 to be electrically connected to the organic EL elements 5 having different linear sections of the light-emitting layer 52 among the linear sections of the light-emitting layer 52, when the transistor Qenb arranged between the VDD line 81 and the anode 51 of the organic EL element 5 is conducting and the threshold detection current i_{prog} is flowing. Thus, these VDD lines 81 are assumed to be connected to, as loads, the capacitance components CEL of the organic EL elements 5 having the different linear sections of the light-emitting layer 52. Hence, even when the thickness is different for each of the linear sections of the light-emitting layer 52, the load of the VDD line 81 is less likely to depend on the thickness of the specific linear section of the light-emitting layer 52. As a result of this, the VDD lines 81 are less likely to vary in the amount of voltage drop. This can reduce the streak pattern corresponding to the banks 3a that is displayed in the light emission period. That is, the organic EL display apparatus according to Embodiment 2 can reduce the display unevenness, as with the organic EL display apparatus 1 according to Embodiment 1.

To be more specific, according to the organic EL display apparatus according to Embodiment 2, when the threshold voltages of the drive transistors Qd of the red pixels 3R located in the pixels 30 in the k-th row are almost the same as the threshold voltages of the drive transistors Qd of the red pixels 3R located in the pixels 30 in the (k+1)-th row, the threshold voltages Vₜₕ detected in the Vth detection period are almost the same.

It should be noted that, for example, “the pixels 30 in the k-th row” refer to the pixels 30 which are in the k-th row counted from the positive side of the column direction (i.e., from the positive side of the Y-axis direction), in the case where the pixels 30 each including the pixels 3R, 3G, and 3B corresponding to the three colors (red, green, and blue) are arranged in a matrix with rows (in a direction parallel to the X axis) and columns (in a direction parallel to the Y axis). To be more specific, a single pixel row includes a plurality of pixels 30 arranged in the row direction (which is parallel to the X axis). Similarly, a single pixel column includes a plurality of pixels 30 arranged in the column direction (which is parallel to the Y axis).

On the other hand, in such an arrangement in which each of the VDD lines 81 is parallel to the banks 3a, even when the threshold voltages of the drive transistors Qd of the red pixels 3R located in the pixels 30 in the k-th row are almost the same as the threshold voltages of the drive transistors Qd of the red pixels 3R located in the pixels 30 in the (k+1)-th row, the threshold voltages Vₜₕ detected in the Vth detection period may possibly be different from each other. More specifically, the streak pattern corresponding to the banks 3a may possibly be displayed.

### [Conclusion]

As described above, the organic EL display apparatus according to Embodiment 2 is almost the same as the organic EL display apparatus 1 according to Embodiment 1, and is different in that the VDD lines 81 function as the aforementioned power supply lines 8. To be more specific, Embodiment 2 is different from Embodiment 1 in that each of the VDD lines 81 (one aspect of the power supply lines 8 according to the present disclosure) in place of the VREF lines 83 in Embodiment 1 is arranged to cross the banks 3a as viewed from above. With this, the organic EL display apparatus according to Embodiment 2 can achieve the same advantageous effects as the organic EL display apparatus 1 according to Embodiment 1.

To be more specific, the voltage drop caused to the VDD line 81 influences the result of the detection of the threshold voltage of the drive transistor Qd. Thus, the variations in the amount of voltage drop among the VDD lines 81 cause the display unevenness. However, the arrangement in which each of the VDD lines 81 crosses the banks 3a can reduce the variations in the amount of voltage drop among the VDD lines 81. Hence, the display unevenness can be reduced.

It should be noted that the power supply lines other than the VDD lines 81, that is, the VREF lines 83, the VSS lines 82, and VRST lines 84 may be arranged in any manner. For example, these power supply lines may be arranged in parallel to the banks 3a (as viewed from the positive side of the Z-axis direction).

### Embodiment 3

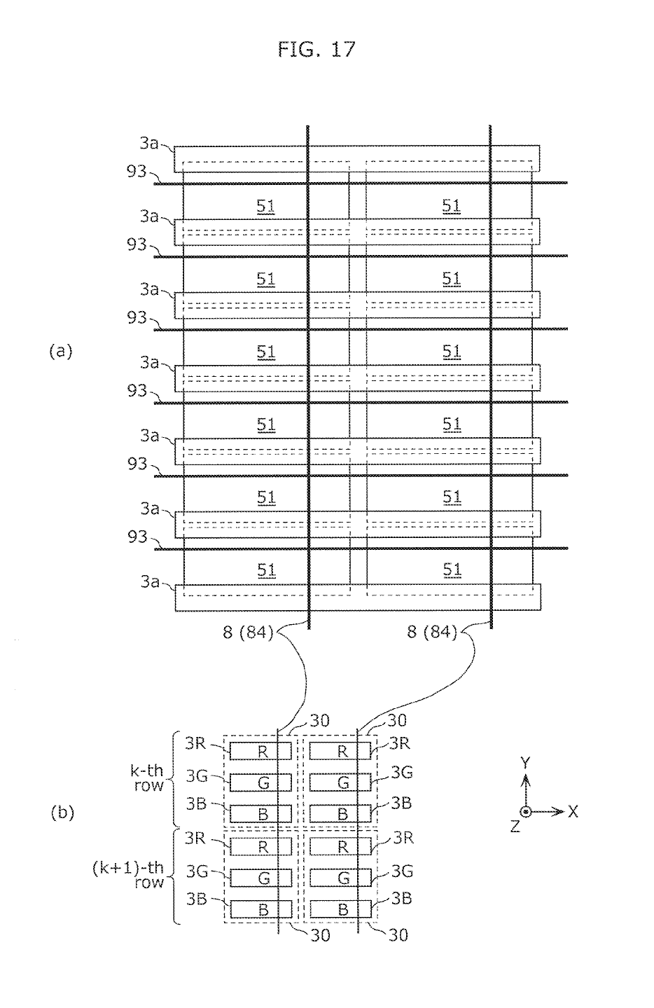

Next, Embodiment 3 is described below. An organic EL display apparatus according to Embodiment 3 is almost the same as the organic EL display apparatus 1 according to Embodiment 1 described above, except that the organic EL display apparatus according to Embodiment 3 includes VRST lines 84 in place of the VREF lines 83, as power supply lines 8 arranged to cross banks 3a as viewed from above. The following describes the organic EL display apparatus according to Embodiment 3, with reference to FIG. 16 and FIG. 17.

### [Influence of Capacitance Component of Organic EL Element on Voltage of Power Supply Line (VRST Line)]

First, a further finding of the inventors as a factor responsible for the aforementioned streak pattern displayed corresponding to the banks 3a is described, with reference to FIG. 16.

### {State of Pixel Circuit in EL Reset Period}

FIG. 16 is an explanatory view showing a state of a pixel circuit 4 in an EL reset period shown in FIG. 5, according to Embodiment 3.

As shown in FIG. 16, in the EL reset period, only the RESET2 signal has a HIGH voltage level and thereby only the transistor Qrst is electrically conducting. As a result, an electrical charge carried by a capacitance component CEL of an organic EL element 5 is reset. Then, a current iᵣₛₜ flows from a source of a drive transistor Qd to the VRST line 84 via the transistor Qrst.

Here, a voltage drop (a voltage depression) due to a wiring resistance of the VRST line 84 occurs to this VRST line 84 to which the current iᵣₛₜ flows. Such a voltage drop may possibly have an influence on a display screen of the organic EL display apparatus. For example, the layout of the VRST lines 84 in the organic EL display apparatus is constrained by the other lines, electrodes, and so forth formed in the same layer as the VRST line 84. On this account, the VRST line 84 has a wiring resistance with a size that should not be ignored. More specifically, when the current passes through the VRST line 84, the voltage drop (the voltage depression) of this VRST line 84 due to the wiring resistance becomes too large to be ignored and thereby may possibly have an influence on the display screen of the organic EL display apparatus 1.

To be more specific, in the EL reset period, a voltage V_{RST} supplied to the pixel circuit 4 from the VRST line 84 is higher than a voltage V_{RST0} supplied to the voltage V_{RST} from a power source unit provided outside the pixel circuits 4. That is, the voltage drop occurs to the VRST line 84 in the EL reset period. The magnitude of this voltage drop depends on the capacitance component CEL of the organic EL element 5. This is because the amount of voltage drop occurring to the VRST line 84 depends on the discharging current from the capacitance component CEL having the capacity G_{EL} in the organic EL element 5. In other words, the voltage V_{RST} has a dependence on the capacitance component CEL of the organic EL element 5.

The following describes the reason why the voltage V_{RST} has a dependence on the capacitance component CEL of the organic EL element 5, using Expressions 17 to 20.

First, assuming that a source voltage of the drive transistor Qd is Vₛ, the current iᵣₛₜ is represented by Expression 17 below,

$$\begin{matrix}[ Math . 15 ] & \\ {i}_{rst} = - {C}_{EL} \frac{d {V}_{s}}{d t} & Expression 17\end{matrix}$$

It can be understood from Expression 17 that the current iᵣₛₜ is influenced by the capacity C_{EL} of the capacitance component CEL of the organic electrode element 5.

Thus, assuming that a wiring resistance corresponding to the pixel 3 among the wiring resistances of the VRST line 84 is R and that the voltage supplied from outside the pixel circuits 4 to each of the VRST lines 84 is V_{RST0}, the voltage V_{RST} supplied from the VRST line 84 to the corresponding pixel circuit 4 is represented by Expression 18 below.

$$\begin{matrix}[ Math . 16 ] & \\ \begin{matrix}{V}_{RST} = {V}_{RST 0} + \sum {Ri}_{rst} \\ = {V}_{RST 0} - \sum {RC}_{EL} \frac{d {V}_{s}}{d t}\end{matrix} & Expression 18\end{matrix}$$

More specifically, the voltage V_{RST} supplied from the VRST line 84 to the corresponding pixel circuit 4 is influenced by the capacity C_{EL} of the capacitance component CEL of the organic electrode element 5. Thus, as represented by Expression 4, the current iᵣₛₜ flowing to the VRST line 84 is influenced by the capacity Cₐ of the capacitance component CEL, and thereby the voltage V_{RST} is influenced by the capacity C_{EL} of the capacitance component CEL as well. In other words, the voltage V_{RST} has a dependence on the capacitance component CEL of the organic EL element 5.

Thus, the source voltage Vₛ of the drive transistor Qd at the finish time of the EL reset period (the time shown in FIG. 5) has a dependence on the capacitance component CEL of the organic EL element 5. To be more specific, the source voltage Vₛ of the drive transistor Qd at the start time of the Vth detection period (the time t13 shown in FIG. 5) has a dependence on the capacitance component CEL of the organic EL element 5.

Here, a gate-source voltage V_{gs} (0) of the drive transistor Qd at the start time of the Vth detection period can be represented by Expression 19 below.

V_{gs}(0)=V_{REF}−_{RST} Expression 19

Thus, it can be understood from Expressions 18 and 19 that V_{gs} (0) has a dependence on the capacitance component CEL of the organic EL element 5.

Moreover, as described in Embodiment 1, assuming that an elapsed time from the start time t13 of the Vth detection period is t, the gate-source voltage V_{gs} (t) of the drive transistor Qd at a time after the elapsed time t from the start time t13 of the Vth detection period is represented by Expression 20 below.

$$\begin{matrix}[ Math . 17 ] & \\ {V}_{gs} ( t ) = \frac{1}{\frac{β \cdot t}{2 ( {C}_{S} + {C}_{EL} )} + \frac{1}{{V}_{gs} ( 0 ) - {V}_{th}}} + {V}_{th} & Expression 20\end{matrix}$$

Thus, it can be understood that when V_{gs} (0) has a dependence on the capacitance component CEL of the organic EL element 5, V_{gs} (t) similarly has a dependence on the capacitance component CEL of the organic EL element 5. More specifically, it can be understood that the threshold voltage Vₜₕ detected in the Vth detection period has a dependence on the capacitance component CEL of the organic EL element 5.

The inventors have found that the capacitance component CEL of the organic EL element 5 that influences the threshold voltage Vth is a main factor responsible for the aforementioned streak pattern displayed corresponding to the banks 3a. The following describes the reason why the capacitance component CEL of the organic EL element 5 causes the streak pattern to be displayed.

As described in Embodiment 1, the capacitance component CEL of the organic EL element 5 is determined by the thickness of the light-emitting layer 52 interposed between the anode 51 and the cathode 53 of this organic EL element 5. The thickness of the light-emitting layer 52 may possibly be different for each of linear sections of the light-emitting layer 52 partitioned by the banks 3a. Thus, the capacities C_{EL} of the capacitance components CEL included in the pixel circuits 4 of the pixels 3 corresponding to the same linear section of the light-emitting layer 52 are substantially the same. However, the capacities C_{EL} of the capacitance components CEL included in the pixel circuits 4 of the pixels 3 corresponding to different linear sections of the light-emitting layer 52 may possibly be different from each other.

For this reason, when the VRST lines 84 are arranged in parallel to the banks 3a, the following problem is caused as in the case where the VREF lines 83 are arranged in parallel to the banks 3a as described in Embodiment 1. That is, the VRST lines 84 vary in the amount of voltage drop.

As described above, the threshold voltage Vₜₕ detected in the Vth detection period depends on the gate-source voltage V_{ds} (0) of the drive transistor Qd at the start time of the Vth detection period. More specifically, the threshold voltage Vₜₕ of the drive transistor Qd depends on the voltage V_{RST} of the VRST line 84 connected to the pixel circuit 4 including this drive transistor Qd. On this account, the variations in the amount of voltage drop among the VRST lines 84 influence the threshold voltage Vₜₕ to be detected. As a result of the arrangement in which the VRST lines 84 are parallel to the banks 3a, the streak pattern corresponding to the linear sections of the light-emitting layer 52 is displayed.

In view of this, the organic EL display apparatus according to Embodiment 3 include the power supply lines 8 which are arranged to cross the banks 3a to reduce such a streak pattern displayed corresponding to the banks 3a. To be more specific, each of the VRST lines 84, which are the power supply lines 8, is arranged to cross the banks 3a.

The following describes the arrangement of the VRST lines 84, which are the power supply lines 8 in Embodiment 3, with reference to FIG. 17. FIG. 17 is a diagram showing the arrangement of the power supply lines 8 (the VRST lines 84) and the banks 3a in the organic EL display apparatus according to Embodiment 3. To be more specific, (a) of FIG. 17 is an enlarged top view of a part of the organic EL display apparatus, and (b) of FIG. 17 is a schematic diagram showing an arrangement of the pixels 3 corresponding to (a) of FIG. 17. It should be noted that although (a) of FIG. 17 is a top view of the organic EL display apparatus viewed from the positive side of the Z-axis direction, the structural elements other than the banks 3a, the anodes 51, the power supply lines 8 (the VRST lines 84), and second RESET lines 93 are not illustrated. Note also that the power supply lines 8 (the VRST lines 84) and the second RESET lines 93 are shown in a manner that the banks 3a and the anodes 51 are drawn in perspective.

As shown in (b) of FIG. 17, pixels 30, each of which includes pixels 3R, 3G, and 3B corresponding to the three colors (red, green, and blue) are shown in a matrix with two rows and two columns. The pixels 3R, 3G, and 3B are divided by color by the banks 3a.

The second RESET lines 93 are arranged, for example, in parallel to the banks 3a, and supply RESET2 signals to the pixels 3 (the pixels 3R, 3G, and 3B). It should be noted that the first RESET lines 92 may be bound outside the pixels 3, for each of the pixels 30 including the pixels 3R, 3G, and 3B.

Here, each of the VRST lines 84 is arranged to cross the banks 3a. To be more specific, the amount of voltage drop of one of the VRST lines 84 depends on the thicknesses of the linear sections of the light-emitting layer 52 partitioned by the banks 3a. Similarly, the amount of voltage drop of another one of the VRST lines 84 depends on the thicknesses of the linear sections of the light-emitting layer 52 partitioned by the banks 3a. Therefore, the VRST lines 84 are less likely to vary in the amount of voltage drop.

As a result, the threshold voltages Vₜₕ detected in the Vth detection period are also less likely to have variations that depend on the thicknesses of the linear sections of the partitioned light-emitting layer 52. Hence, the organic EL display apparatus according to Embodiment 3 can achieve the same advantageous effects as the organic EL display apparatus 1 according to Embodiment 1.

To be more specific, such an arrangement, in which each of the VRST lines 84 crosses the banks 3a, allows the VRST line 84 to be electrically connected to the organic EL elements 5 having different linear sections of the light-emitting layer 52 among the linear sections of the light-emitting layer 52, when the transistor Qrst arranged between the VRST line 84 and the anode 51 of the organic EL element 5 is conducting. Thus, these VRST lines 84 are assumed to be connected to, as loads, the capacitance components CEL of the organic EL elements 5 having the different linear sections of the light-emitting layer 52. Hence, even when the thickness is different for each of the linear sections of the light-emitting layer 52, the load of the VRST line 84 is less likely to depend on the thickness of the specific linear section of the light-emitting layer 52. As a result of this, the VRST lines 84 are less likely to vary in the amount of voltage drop. This can reduce the streak pattern corresponding to the banks 3a that is displayed in the light emission period. That is, the organic EL display apparatus according to Embodiment 3 can reduce the display unevenness, as with the organic EL display apparatus 1 according to Embodiment 1.

To be more specific, according to the organic EL display apparatus according to Embodiment 3, when the threshold voltages of the drive transistors Qd of the red pixels 3R located in the pixels 30 in a k-th row are almost the same as the threshold voltages of the drive transistors Qd of the red pixels 3R located in the pixels 30 in a (k+1)-th row, the threshold voltages Vₜₕ detected in the Vth detection period are almost the same.

On the other hand, in such an arrangement in which each of the VRST lines 84 is parallel to the banks 3a, even when the threshold voltages of the drive transistors Qd of the red pixels 3R located in the pixels 30 in the k-th row are almost the same as the threshold voltages of the drive transistors Qd of the red pixels 3R located in the pixels 30 in the (k+1)-th row, the threshold voltages Vₜₕ detected in the Vth detection period may possibly be different from each other. More specifically, the streak pattern corresponding to the banks 3a may possibly be displayed.

### [Conclusion]

As described above, the organic EL display apparatus according to Embodiment 3 is almost the same as the organic EL display apparatus 1 according to Embodiment 1, and is different in that the VRST lines 84 function as the aforementioned power supply lines 8. To be more specific, Embodiment 3 is different from Embodiment 1 in that each of the VRST lines 84 (one aspect of the power supply lines 8 according to the present disclosure) in place of the VREF lines 83 in Embodiment 1 is arranged to cross the banks 3a as viewed from above. With this, the organic EL display apparatus according to Embodiment 3 can achieve the same advantageous effects as the organic EL display apparatus 1 according to Embodiment 1.

TO be more specific, the organic EL display apparatus according to Embodiment 3 includes the following: the VRST lines 84 each for supplying the reset voltage V_{RST} to reset the voltage held by the organic EL element 5 of the corresponding pixel 3; and the VDD lines 81 each connected to the drain of the drive transistor Qd and each for supplying the current to cause the organic EL element 5 of the corresponding pixel 3 to emit light. Each of the pixels 30 has the transistor Qrst that switches the states between the VRST line 84 and the second electrode of the storage capacitor Cs and between the VRST line 84 and the anode 51 of the organic EL element 5, between conducting and non-conducting states.

Here, when the electrical charge accumulated in the capacitance component CEL of the organic EL element 5 is reset to detect the threshold voltage of the drive transistor Qd, the current iᵣₛₜ corresponding to this electrical charge passes through the VRST line 84 and thereby causes the voltage drop. The voltage drop caused to the VRST line 84 influences the result of the detection of the threshold voltage of the drive transistor Qd. Thus, the variations in the amount of voltage drop among the VRST lines 84 cause the display unevenness. However, the arrangement in which each of the VRST lines 84 crosses the banks 3a can reduce the variations in the amount of voltage drop among the VRST lines 84. Hence, the display unevenness can be reduced.

It should be noted that the power supply lines other than the VRST line 84, that is, the VDD lines 81, the VREF lines 83, and the VSS lines 82 may be arranged in any manner. For example, these power supply lines may be arranged in parallel to the banks 3a (as viewed from the positive side of the Z-axis direction).

### (Other Modifications)

Although the organic display apparatuses have been described based on Embodiments according to the present disclosure thus far, the present disclosure is not limited to Embodiments described above.

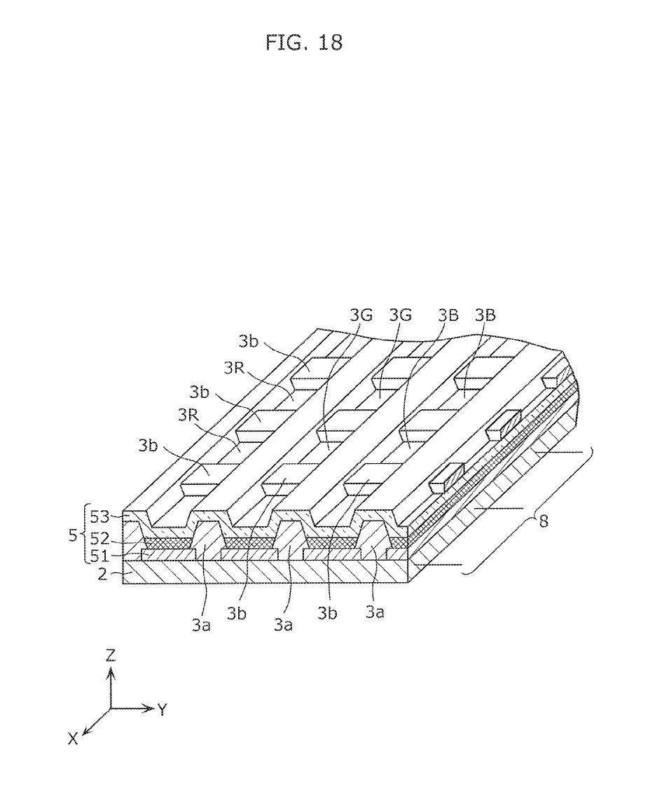

For example, as shown in FIG. 18, an organic EL display apparatus may further include a plurality of banks 3b (second partitions) which cross a plurality of banks 3a (first partitions). The banks 3b partition, in conjunction with the banks 3a, a light-emitting layer 52 into a grid of squares. The banks 3a may protrude upward higher than the banks 3b. FIG. 18 is a perspective view showing an example of the banks in the organic EL display apparatus according to another modification. As shown in FIG. 18, the banks 3a and the banks 3b function as pixel banks each having an opening for each of pixels 3.

Thus, in a process of manufacturing the organic EL display apparatus as with the processes of manufacturing the organic EL display apparatuses in the above embodiments, at least one of layers included in the light-emitting layer 52 can be formed by dropping an organic semiconductor material solution to a pixel row located between two adjacent banks 3a. To be more specific, at the time of dropping the organic semiconductor material solution, this organic semiconductor material solution is formed, spreading over the banks 3b. However, subsequent processes, such as heat treatment, eliminate the organic semiconductor material solution spreading over the banks 3b. As a result, an organic layer comprising the organic semiconductor material is formed only in the openings of the pixel banks. Thus, the organic layer can be formed in the openings of the pixel banks by a simple manufacturing process. More specifically, the light-emitting layer can be formed in the openings of the grid by a simple manufacturing process.

As in the organic EL display apparatuses described above, even such an organic EL display apparatus includes the light-emitting layer 52 which is formed by dropping the organic semiconductor material solution to the pixel row located between two adjacent banks 3a. Thus, although the light-emitting layers 52 of the pixels 3 in the same pixel row are almost the same in thickness, the light-emitting layers 52 of the pixels 3 in different rows may possibly be different in thickness.

Moreover, a predetermined surface treatment using, for example, fluorine may be performed on each of the banks 3a to enable the surface of the bank 3a to have liquid repellency. With this, the organic semiconductor material solution on the surfaces of the banks 3b out of the organic semiconductor material solution spreading over the banks 3b are repelled. Thus, the layer that is included among the layers (a hole injection layer 521, a hole transport layer 522, an organic light-emitting layer 523, an electron transport layer 524, and an electron injection layer 525) of the light-emitting layer 52 and is formed from the organic semiconductor material solution is divided for each of the pixels 3.

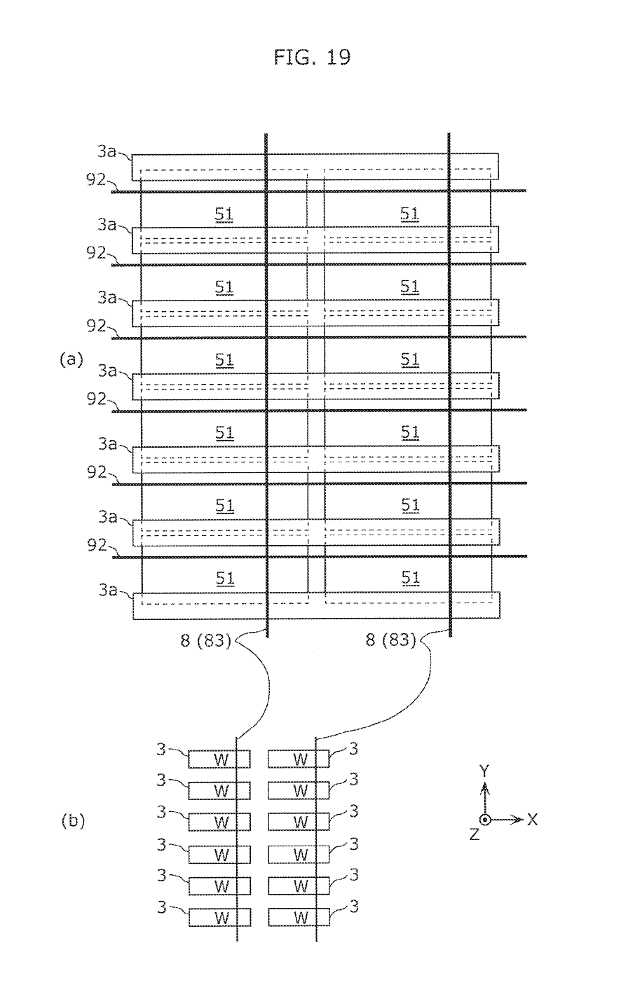

Furthermore, the banks 3a are provided to divide the pixels 3 having different colors in the above description. However, the banks 3a may be provided to divide the pixels 3 having the same color, as shown in FIG. 19.

FIG. 19 is a diagram showing an arrangement of power supply lines 8 (VREF lines 83, for example) and the banks 3a in an organic EL display apparatus according to another modification.

As shown in FIG. 19, for example, assume that all the pixels 3 have the same color (such as white) and that each of the power supply lines 8 (the VREF lines 83, for example) is arranged in parallel to the banks 3a. Here, even when DATA signal voltages V_{DATA} with the same luminance are applied to the pixels 3 of rows, the pixels 3 in the different rows may possibly emit light of different luminances. In other words, the streak pattern corresponding to the banks 3 may possibly be displayed.

On the other hand, according to the organic EL display apparatus according to this modification, each of the power supply lines 8 (the VREF lines 83, for example) is arranged to cross the banks 3a. With this, when the DATA signal voltages V_{DATA} with the same luminance are applied to the pixels 3 in the rows, the pixels 3 in the rows can emit light of almost the same luminance. Hence, the organic EL display apparatus according to this modification can achieve the same advantageous effects as in Embodiment 1.

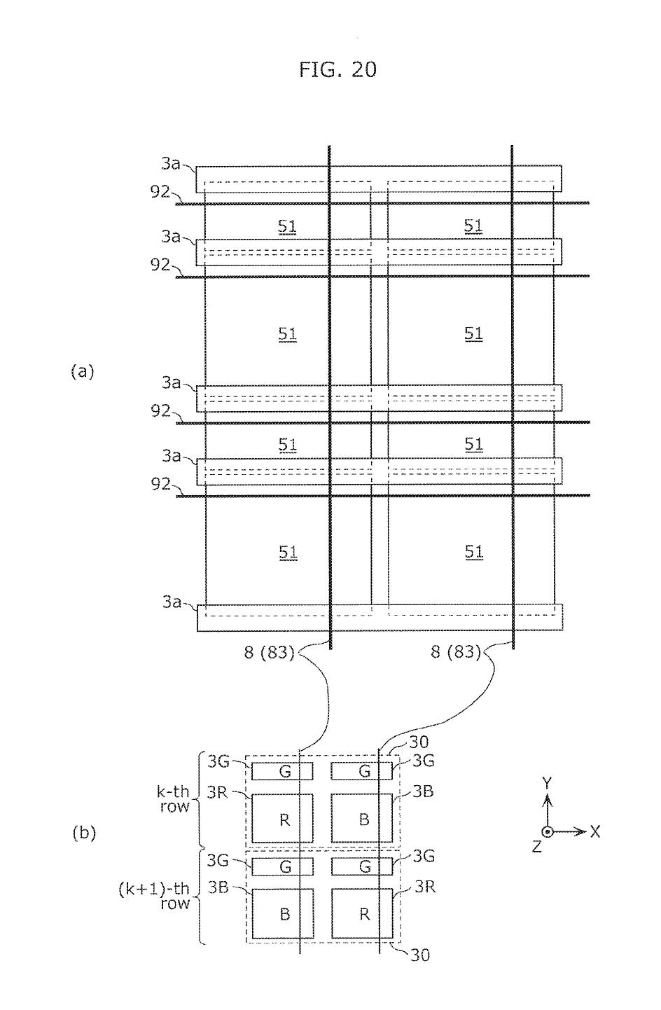

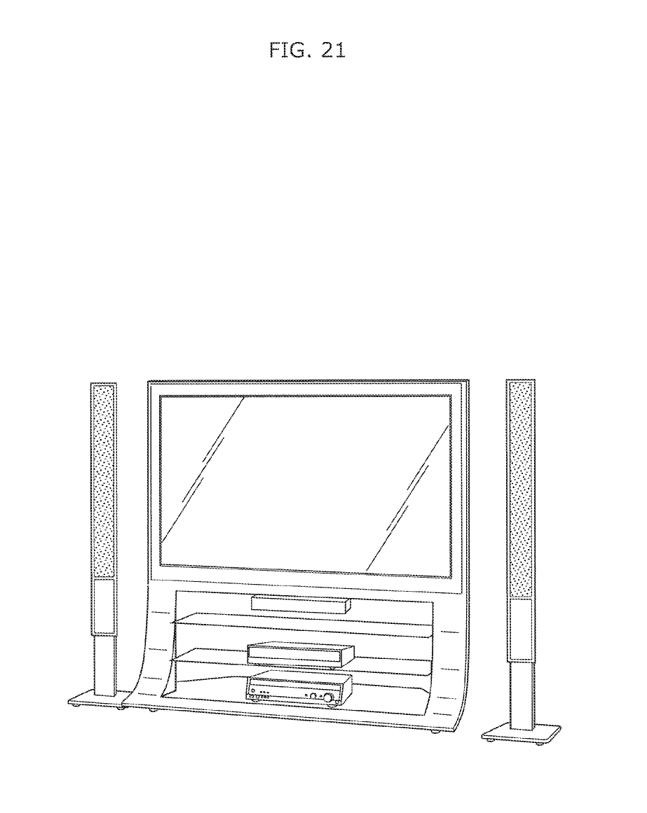

Moreover, each of the banks 3a is provided to divide the pixels 3 of the different colors in the above description. To be more specific, each of the linear section of the light-emitting layer 52 is provided corresponding to the pixels 3 of the same color. However, the present disclosure is not limited to this. FIG. 20 is a diagram showing an arrangement of power supply lines 8 (VREF lines 83, for example) and banks 3a in an organic EL display apparatus according to another modification. As shown in FIG. 20, a plurality of pixels may be arranged in, for example, a PenTile matrix in which pixels of different colors are arranged in the same row.

Furthermore, the light-emitting layer 52 includes the hole injection layer 521, the hole transport layer 522, the organic light-emitting layer 523, the electron transport layer 524, and the electron injection layer 525 in the above description. However, the light-emitting layer 52 may not include these layers other than the organic light-emitting layer 523.

Furthermore, forms obtainable by performing various modifications on the respective embodiments and modifications that may be conceived by a person of ordinary skill in the art as well as forms realized by arbitrarily combining the structural elements and functions in the respective embodiments and modifications without departing from the scope of the teachings of the present disclosure are included in the present disclosure.

### INDUSTRIAL APPLICABILITY

The present disclosure can be used for a display apparatus, and particularly for a flat panel display (FPD) apparatus, such as a television set as shown in FIG. 21 for example.

### REFERENCE SIGNS LIST

1 organic EL display apparatus
2 thin-film transistor array device
3, 3B, 3G, 3R, 30 pixel
3a, 3b bank
4, 4A pixel circuit
5 organic EL element
6 SCAN line
7, 7A DATA The
8 power supply line
9 transparent sealing film
51 anode
52 light-emitting layer
53 cathode
81 VDD line
82 VSS line
83 VREF line
84 VRST line
91 ENABLE line
92 first RESET line
93 second RESET line
201 substrate
202 drive circuit layer
310 transparent sealing film
521 hole injection layer
522 hole transport layer
523 organic light-emitting layer
524 electron transport layer
525 electron injection layer
Cs storage capacitor
CEL capacitance component
Qd drive transistor
Qenb, Qref, Qrst, Qscan transistor

1. A display apparatus including a plurality of pixels, the display apparatus comprising:
a circuit substrate;
a light-emitting layer which is provided above the circuit substrate;
a plurality of first partitions which partition the light-emitting layer into a plurality of linear sections; and
a plurality of power supply lines which are provided for the circuit substrate and supply a predetermined voltage to the plurality of pixels,
wherein each of the plurality of pixels has:
a light-emitting element which includes a part of the light-emitting layer partitioned into the plurality of linear sections and emits light corresponding to a supplied current;
a drive transistor which supplies a current to the light-emitting element; and
a storage capacitor which stores a threshold voltage of the drive transistor, and
each of the plurality of power supply lines is arranged to cross the plurality of first partitions as viewed from above.

2. The display apparatus according to claim 1, further comprising
a plurality of second partitions which are arranged to cross the plurality of first partitions and partition, in conjunction with the plurality of first partitions, the light-emitting layer into a grid of squares,
wherein the plurality of first partitions protrude upward higher than the plurality of second partitions.

3. The display apparatus according to claim 1,
wherein the light-emitting element further includes an anode and a cathode which are provided above the circuit substrate and disposed opposite to each other via the part of the light-emitting layer partitioned into the plurality of linear sections, and
the light-emitting layer includes a hole injection layer, a hole transport layer, an organic light-emitting layer, an electron transport layer, and an electron injection layer which are laminated from an anode side in stated order.

4. The display apparatus according to claim 3,
wherein at least one of the hole injection layer, the hole transport layer, the organic light-emitting layer, the electron transport layer, and the electron injection layer is formed by a printing method.

5. The display apparatus according to claim 1,
wherein each of the plurality of power supply lines is arranged to be orthogonal to the plurality of first partitions as viewed from above.

6. The display apparatus according to claim 1,
wherein the storage capacitor has: a first electrode which is electrically connected to a gate of the drive transistor; and a second electrode which is electrically connected to a source of the drive transistor and to an anode of the light-emitting element,
the display apparatus comprises:
a plurality of reference voltage supply lines which supply a reference voltage used as a reference to detect the threshold voltage for each of the plurality of pixels; and
a plurality of positive supply lines each of which is electrically connected to a drain of the drive transistor and supplies a current that causes the light-emitting element of the pixel to emit light,
each of the plurality of pixels further has a first switch for switching a state between the reference voltage supply line and the first electrode of the storage capacitor, between conducting and non-conducting states, and
at least one of the plurality of reference voltage supply lines and the plurality of positive supply lines is the plurality of power supply lines.

7. The display apparatus according to claim 6, comprising
a plurality of signal lines, as the plurality of reference voltage supply lines, which supply the reference voltage and a signal voltage that determines luminance of the plurality of pixels.

8. The display apparatus according to claim 1,
wherein the storage capacitor has: a first electrode which is electrically connected to a gate of the drive transistor; and a second electrode which is electrically connected to a source of the drive transistor and to an anode of the light-emitting element,
the display apparatus comprises:
a plurality of reset power supply lines which supply a reset voltage for resetting a voltage held by the light-emitting element for each of the plurality of pixels; and
a plurality of positive supply lines each of which is electrically connected to a drain of the drive transistor and supplies a current that causes the light-emitting element of the pixel to emit light,
each of the plurality of pixels further has a second switch for switching a state between the reset power supply line and the second electrode of the storage capacitor and a state between the reset power supply line and the anode of the light-emitting element, between conducting and non-conducting states, and
at least one of the plurality of reset power supply lines and the plurality of positive supply lines is the plurality of power supply lines.
